(19) United States
(12) Patent Application Publication
(10) Pub. No.: US 2022/0380934 A1
(43) Pub. Date: Dec. 1, 2022

(54) SUBSTRATE DIRECTED SYNTHESIS OF TRANSITION-METAL DICHALCOGENIDE CRYSTALS WITH TUNABLE DIMENSIONALITY AND OPTICAL PROPERTIES

(71) Applicant: The Johns Hopkins University, Baltimore, MD (US)

(72) Inventors: Thomas Kempa, Baltimore, MD (US); Tornojit Chowdhury, Baltimore, MD (US); Jungkil Kim, Baltimore, MD (US); Erick Sadler, Baltimore, MD (US)

(73) Assignee: The Johns Hopkins University, Baltimore, MD (US)

(21) Appl. No.: 17/776,511

(22) PCT Filed: Nov. 16, 2020
(86) PCT No.: PCT/US2020/060727

§ 371 Date: May 12, 2022

Related U.S. Application Data
(60) Provisional application No. 62/936,112, filed on Nov. 15, 2019.

(51) Int. Cl. C30B 29/48; G02F 1/00; G02F 1/03; C30B 25/18; C30B 29/60

(52) U.S. Cl. CPC C30B 29/48; G02F 1/0027; G02F 1/0305; C30B 25/186; C30B 29/60

(57) ABSTRACT

A method of producing transition-metal dichalcogenide crystals includes providing a silicon substrate having a phosphine-treated surface, exposing the phosphine-treated surface of the silicon substrate to a vapor containing a transition metal, and exposing the phosphine-treated surface of the silicon substrate to a vapor containing a chalcogen. A crystal of the transition-metal and the chalcogen is formed on the phosphine-treated surface of the silicon substrate to produce a transition-metal dichalcogenide crystal by chemical vapor deposition.

### CROSS REFERENCE TO RELATED APPLICATIONS

The present application claims priority benefit from U.S. Provisional Patent Application No. 62/936,112 filed on Nov. 15, 2019, the entire content of which is incorporated herein by reference. All references cited anywhere in this specification, including the Background and Detailed Description sections, are incorporated by reference as if each had been individually incorporated.

### BACKGROUND

### 1. Technical Field

The presently claimed embodiments of the current invention relate to synthesis of transition-metal dichalcogenide crystals, and more particularly to substrate directed synthesis of transition-metal dichalcogenide crystals with tunable dimensionality and optical properties.

### 2. Discussion of Related Art

Two-dimensional (2D) transition-metal dichalcogenides (TMDs) have been the subject of extensive optoelectronic¹, catalytic^{2,3}, and device studies^{4,5}, because of their tunable bandgap, surface and edge reactivity, layer-dependent properties, and the potential to create multi-layer architectures incorporating atomically abrupt interfaces^{6,7}. The phase and orientation of the layers comprising a TMD crystal are frequently manipulated in order to tune its electronic band structure. Equally important, the micro/nano-structure and dimensionality of a TMD crystal determine many of its physical properties. For example, the structure, density and strain state of edge sites and basal planes defines the selectivity and activity of TMD catalysts^{2,3,8,9}. Moreover, the size and shape of 2D crystals governs their mechanical folding and buckling modes, which, in turn, dictate the family of topologies accessible through application of nanoscale kirigami methods¹⁰. Finally, the shape and extent of electroactive channels in quantum optoelectronic devices is defined through careful patterning of electrodes atop 2D TMD crystals, rendering possible the confinement and manipulation of carriers and excitons^{11,12}.

However, though many desirable material properties are dictated by crystallite micro/nano-structure and dimensionality, there is a lack of synthetic methods for precisely controlling these structural attributes. Explicit synthetic manipulation of crystallite size, shape, phase, and layer number is a major challenge, despite existing vapor-phase growth methods and exfoliation strategies¹³⁻¹⁶ that offer access to layered materials, including 2D TMDs. Furthermore, though lithography and etching can be used to define crystal morphologies and dimensions, these processes have intrinsic resolution limits and are occasionally incompatible with 2D materials. Such synthetic and fabrication challenges impose constraints on the discovery and preparation of 2D materials, and on their integration into devices.

Therefore, there remains a need for improved methods for the synthesis of transition-metal dichalcogenide nanocrystals and for the transition-metal dichalcogenide nanocrystals produced.

### SUMMARY

A method of producing transition-metal dichalcogenide crystals according to an embodiment of the current invention includes providing a silicon substrate having a phosphine-treated surface, exposing the phosphine-treated surface of the silicon substrate to a vapor containing a transition metal, and exposing the phosphine-treated surface of the silicon substrate to a vapor containing a chalcogen. A crystal of the transition-metal and the chalcogen is formed on the phosphine-treated surface of the silicon substrate to produce a transition-metal dichalcogenide crystal by chemical vapor deposition.

A method of treating a silicon substrate for use in producing transition-metal dichalcogenide crystals according to another embodiment of the current invention includes providing a silicon substrate having a Si(001) crystal surface, and exposing the Si(001) crystal surface of the silicon substrate to a dose of phosphine to provide a phosphine treated surface thereof.

A phosphine-treated silicon substrate for use in producing transition-metal dichalcogenide crystals on a phosphine treated surface thereof according to another embodiment of the current invention includes the phosphine treated surface being a modified surface of a Si(001) crystal surface of a silicon substrate so as to have a surface composition containing Si and P in a stoichiometric proportion represent by SiₓP_{y} wherein x and y are each greater than 0 and less than 2 and subject to the constraint x+y=2.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

FIGS. 1A-1G illustrate substrate directed synthesis of 1D MoS₂ nanocrystals with tunable width according to an embodiment of the current invention;

FIGS. 2A-2G show aberration-corrected scanning transmission electron microscopy and spectroscopy of 1D MoS₂ nanocrystals according to an embodiment of the current invention;

FIGS. 3A-3D show optical spectroscopy of 1D and tapered MoS₂ nanocrystals according to an embodiment of the current invention;

FIGS. 4A-4D show experimental and computational support for a proposed mechanism for 1D MoS₂ nanocrystal growth according to an embodiment of the current invention;

FIGS. 5A-5E show position of substrates and reagents in the CVD reactor according to an embodiment of the current invention;

FIGS. 6A-6F show characterization of 2D MoS₂ crystals on SiO₂ according to an embodiment of the current invention;

FIGS. 7A-7E show yield and angular orientation of 1D MoS₂ crystals according to an embodiment of the current invention;

FIGS. 8A-8C show width control of 1D MoS₂ crystals according to an embodiment of the current invention;

FIG. 9 provides SEM images of 1D MoS₂ crystals according to an embodiment of the current invention;

FIG. 10 is a Raman spectrum of 1D MoS₂ according to an embodiment of the current invention;

FIG. 11 shows growth of MoS₂ on PH₃ treated SiO₂ substrates according to an embodiment of the current invention;

FIGS. 12A-12C is an example of MoSe₂ crystals on PH₃-treated Si(001) substrate according to an embodiment of the current invention;

FIGS. 13A and 13B show WS₂ crystals on PH₃-treated Si(001) substrate according to an embodiment of the present invention;

FIGS. 14A and 14B show WSe₂ crystals on PH₃-treated Si(001) substrate according to an embodiment of the present invention;

FIGS. 15A-15F show STEM-HAADF imaging of 1D MoS according to an embodiment of the present invention;

FIG. 16 shows an XPS analysis of 1D MoS₂ according to an embodiment of the present invention;

FIG. 17 is a PL spectrum of single layer 1D MoS₂ according to an embodiment of the present invention;

FIGS. 18A-18C show position dependent PL and Raman spectra from 1D MoS₂ according to an embodiment of the present invention;

FIGS. 19A-19B show time dependent PL spectra from 1D MoS₂ according to an embodiment of the present invention;

FIG. 20 shows 1D MoS₂ crystals grown with tapered profiles according to an embodiment of the present invention;

FIG. 21 is a full-scale PL spectrum from 1D MoS₂ according to an embodiment of the present invention;

FIG. 22 shows I-V characteristics of 1D MoS₂ crystal FET device according to an embodiment of the present invention; and

FIGS. 23A-23C show STEM-HAADF imaging of nano-sized 2D MoS₂ “seed” according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the present invention. All references cited anywhere in this specification are incorporated by reference as if each had been individually incorporated.

As used herein, the notation SiₓP_{y} describes the composition of a surface region of the Si(001) substrate with the constraint x+y=2. The case for y=0 corresponds to no treatment of the silicon substrate. The case for x=0 corresponds to a surface fully coated with P-P dimers. The case for x,y=1 corresponds to a surface fully coated with Si—P dimers. The values of y, and therefore also x due to the constraint x+y=2, will vary depending on the phosphine dose. In some embodiments, a suitable range for x is approximately 0.5 to 1 and for y is approximately 1 to 1.5. The symbol “Si—Pₓ” is sometimes used in the following description. As used herein, it can include, or in some embodiments be the same as, “SiₓP_{y}”.

Two-dimensional (2D) transition-metal dichalcogenide (TMD) crystals are a versatile platform for optoelectronic, catalytic, and quantum device studies. However, the ability to tailor their physical properties through explicit synthetic control of their morphology and dimensionality is a major challenge. Accordingly, an embodiment of the current invention provides a gas-phase synthesis method that significantly transforms the structure and dimensionality of TMD crystals without lithography. Synthesis of MoS₂ on Si(001) surfaces pre-treated with phosphine yields high aspect ratio nanoribbons with uniform widths according to an embodiment of the current invention. In an embodiment, we can systematically control the width of these nanoribbons between 50 nm and 430 nm by varying the total phosphine dosage during the surface treatment step. Aberration-corrected electron microscopy reveals that the nanoribbons are predominantly 2H phase with zig-zag edges and an edge quality that is comparable to or better than that of graphene and TMD nanoribbons prepared through conventional top-down processing. Owing to their restricted dimensionality, the nominally 1D MoS₂ nanocrystals exhibit photoluminescence, which is 50 MeV higher in energy than that from 2D MoS₂ crystals. Moreover, this emission is precisely tunable through synthetic control of the crystal width. Directed crystal growth on designer substrates has the potential to enable the preparation of low-dimensional materials with prescribed morphologies and tunable or emergent optoelectronic properties.

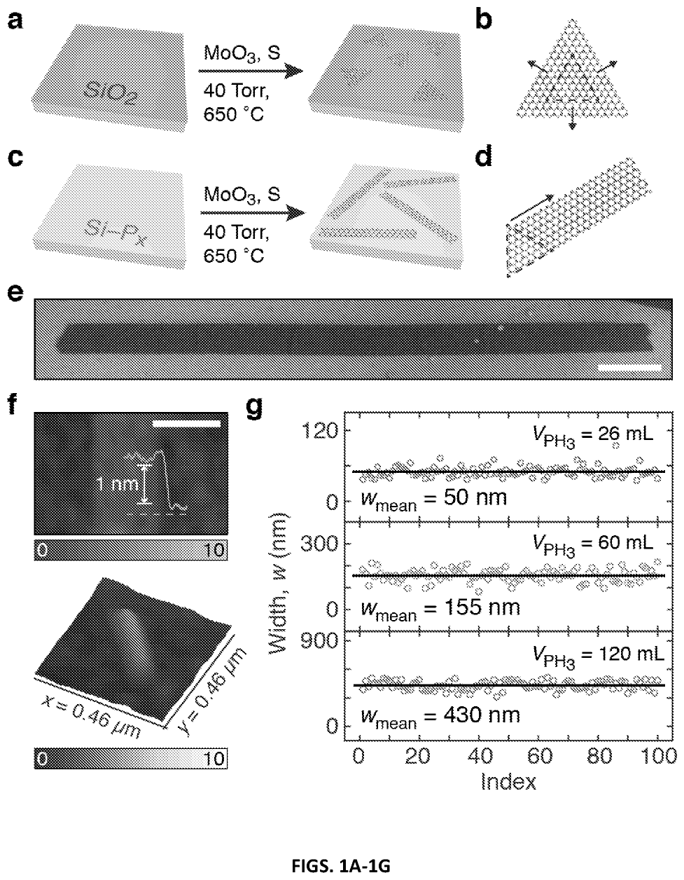

FIGS. 1A-1G illustrate substrate directed synthesis of 1D MoS₂ nanocrystals with tunable width according to an embodiment of the current invention. FIG. 1A, shows a scheme depicting low-pressure synthesis of 2D MoS₂ crystals on SiO₂ according to an embodiment of the current invention. FIG. 1B, is a schematic illustration of the typical omni-directional lateral growth mode that yields triangular 2D MoS₂ crystals on SiO₂ substrates. FIG. 1C, shows a scheme depicting our synthesis of 1D MoS₂ crystals (nanoribbons) on PH₃-treated Si(001) substrates (denoted Si—Pₓ) according to an embodiment of the current invention. FIG. 1D, is schematic illustration of a directed growth mode that yields 1D MoS₂ crystals on Si—Pₓ substrates. It is hypothesized that preferential growth from one of the edges of a nanoscale 2D crystal “seed” leads to formation of the 1D MoS₂ nanoribbon. FIG. 1E, is a high-resolution SEM image of a single 1D MoS₂ crystal. The scale bar is 500 nm. FIG. 1F, shows Top: 2D AFM topographical map of a portion of a single 1D MoS₂ crystal and its corresponding height profile for line scans taken along the orange dotted line noted in the map. Scale bar, 250 nm; Bottom: 3D AFM topographical map of a single 1D MoS₂ crystal showing the significant surface and height uniformity of the crystal. Bars beneath both panels define the height contrast in the AFM maps (scale: 0-10 nm). FIG. 1G, shows average widths (wmean) for 100 randomly sampled 1D MoS₂ crystals grown on Si(001) substrates treated with total PH₃ dosages (V_{pH3}) of 26 mL, 60 mL, and 120 mL. (Note that 1 mL=1 cm³ by definition. The use of one herein can be replaced by the other without any difference in meaning.) Nanoribbon widths were measured by SEM. Solid black lines denote averages.

A method of producing transition-metal dichalcogenide nanocrystals according to an embodiment of the current invention includes providing a phosphine-treated silicon substrate with the surface configuration represented by SiₓP_{y}; exposing the surface of the phosphine-treated silicon substrate to a vapor containing a transition metal; and exposing the surface of the phosphine-treated silicon substrate to a vapor containing a chalcogen. The nanocrystal of the transition-metal and the chalcogen is formed on the surface of the phosphine-treated silicon substrate to produce a transition-metal dichalcogenide nanocrystal by chemical vapor deposition.

After phosphine treatment, the topmost surface of the Si(001) substrate is covered mostly with Si—P dimers and a smaller population of P-P (P2 dimers). At higher phosphine doses the concentration of P2 dimers increases at the expense of Si—P dimers. It is important to note that the “Si—Pₓ” notation is also used here to generically describe a surface comprised of both Si—P and P—P dimers in some ratio to one another. In some embodiments, the surface configuration is SiₓP_{y} with the constraint that x+y=2. For a bare Si surface, y=0, and for a pure P-P dimer coated surface, x=0. Note that we do not get 1D growth when the surface is solely Si or solely P-P. For a pure Si—P dimer coated surface, x,y=1. However, it is important to emphasize that, in some embodiments, some heterogeneity is important to drive 1D growth (e.g., co-existence of Si—P and P-P dimers). Therefore, in some embodiments, an optimal range of x is ˜0.5-1 and for y is ˜1-1.5.

The following describes some further concepts of the current invention by way of particular examples. The general concepts of the current invention are not limited to the particular examples.

Although the examples are for particular wafer sizes, to allow for scaling of our process to 3 inch, or even up to 18 inch, wafers we can expand accordingly the bore of our chemical vapor deposition reactor and adjust the flow rate (in standard cm³ per minute: sccm) of phosphine between no less than 1 sccm and no greater than 1000 sccm, for example.

More generally, larger substrate sizes can be accommodated for phosphine treatment through (1) expansion of the bore of the chemical vapor deposition reactor and (2) an increase in the phosphine flow rate (in standard cm³ per minute) in proportion to the increase in area of the substrate. The concepts of this invention are intended to include cases in which the process is scaled to commercial production systems.

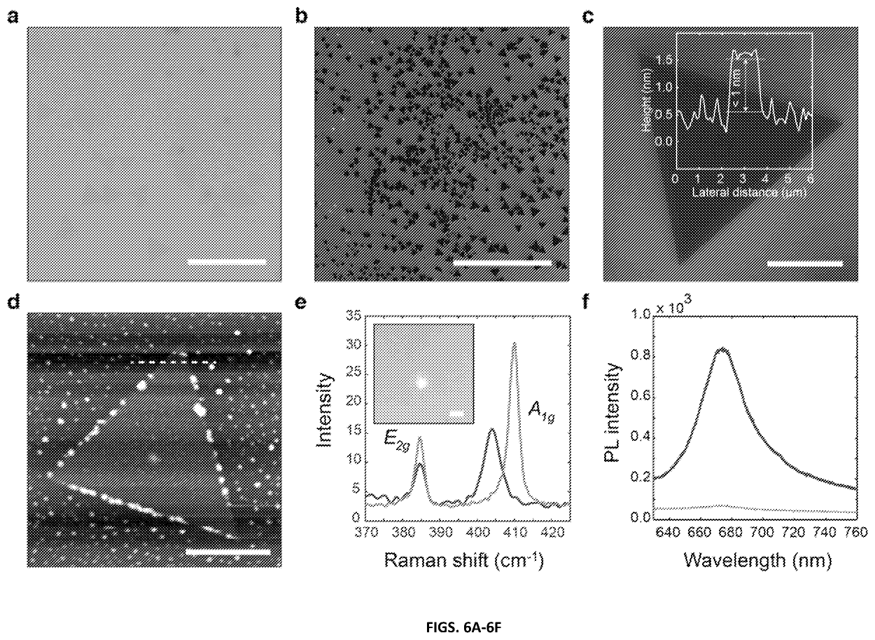

An embodiment of the current invention provides a gas-phase synthesis method to control the micro/nano-structure and dimensionality of 2D TMD crystals (Methods). This synthesis realizes directed growth of TMDs on phosphine-treated Si substrates to yield crystalline TMD nanoribbons with tunable widths (FIGS. 1C, 1D). This directed growth mode differs significantly from the typical omni-directional growth mode responsible for forming triangular 2D TMD crystals on SiO₂ substrates (FIGS. 1A, 1B). These narrow nanoribbons exhibit a significantly blue-shifted emission relative to 2D TMD crystals owing to their restricted dimensionality. This synthetic method involves the use of P atom functionalized Si surfaces, which can direct the in-plane growth of TMD crystals during their synthesis via chemical vapor deposition (CVD) protocols. Salient features and results of our growth method are highlighted in FIGS. 1C-1G. We first developed a low-pressure CVD protocol for TMD synthesis (FIGS. 5A-5E), which is compatible with the P-functionalized Si surfaces, and validated it for the synthesis of MoS₂ on SiO₂ substrates from MoO₃ and S precursors (FIG. 1A). Scanning electron microscopy (SEM), Raman spectroscopy, and atomic force microscopy (AFM) confirm that the majority products of this reaction are single-layer 2D MoS₂ crystals with ˜10 μm edge lengths (FIGS. 6A-6F). These 2D crystals are consistent with those produced through standard chemical vapor transport protocols reported in the literature¹⁷.

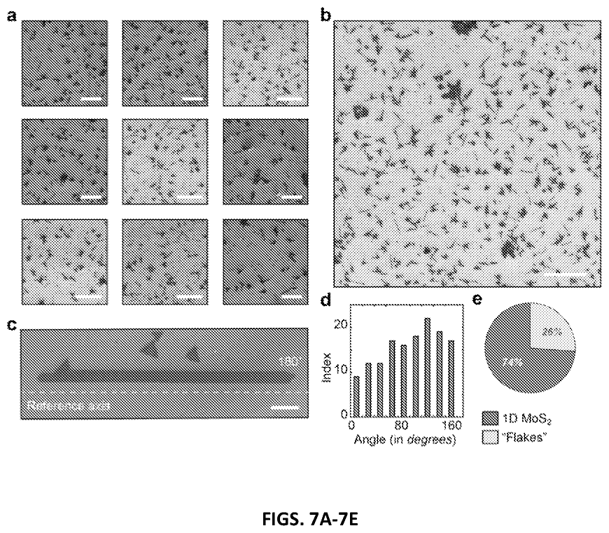

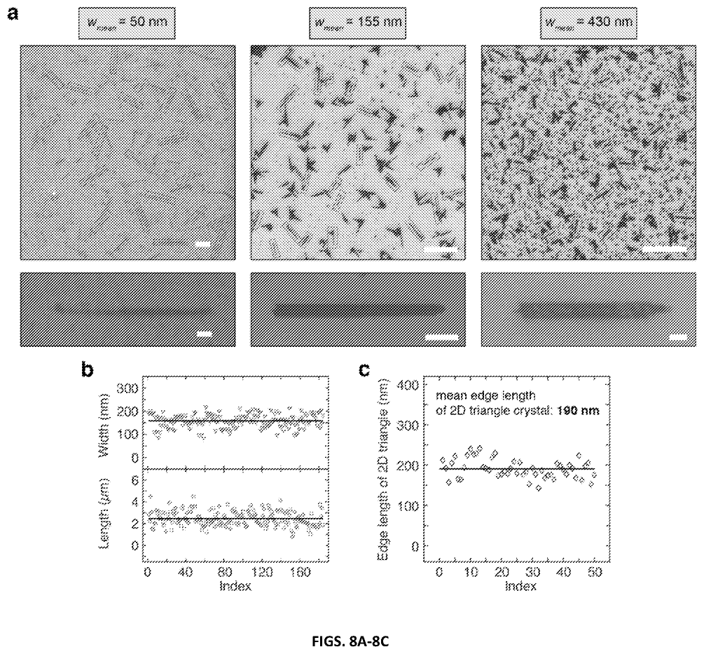

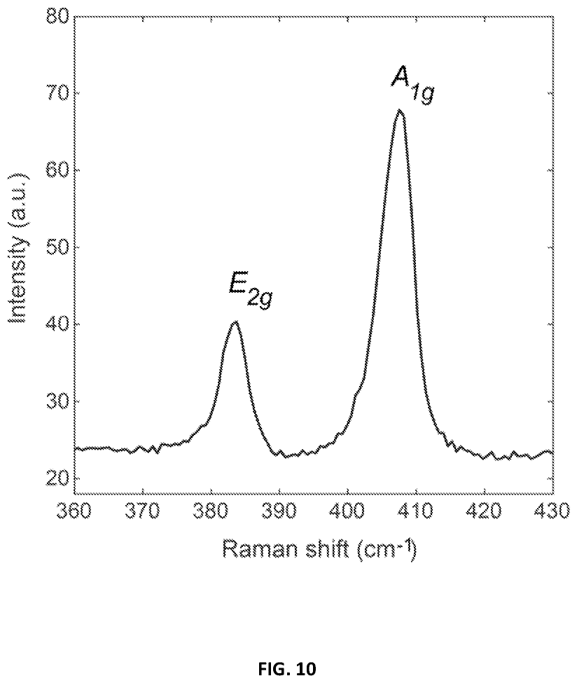

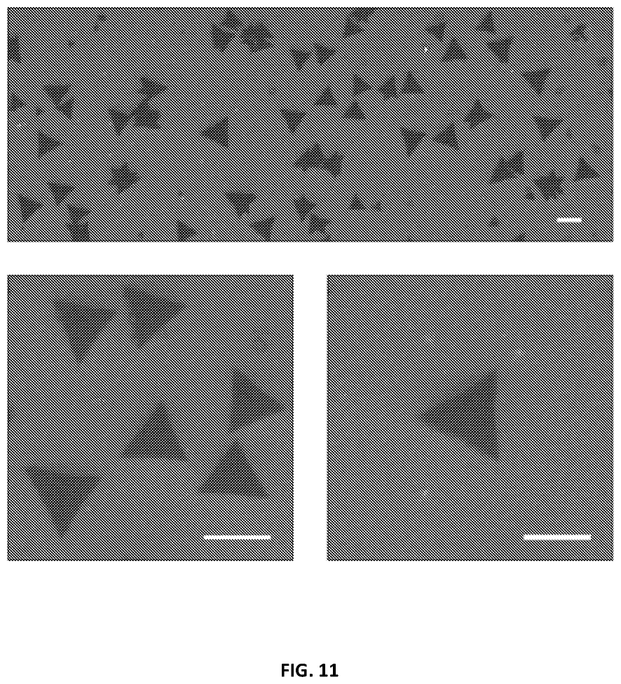

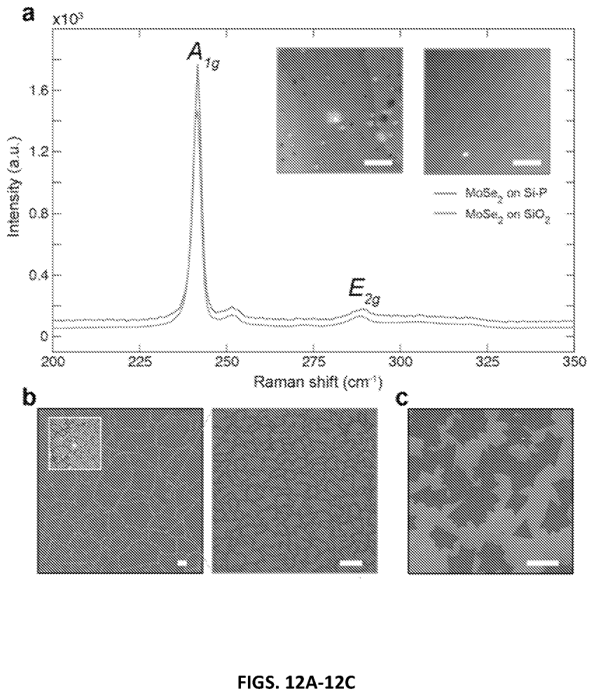

A synthetic innovation, according to an embodiment of the current invention, involves pre-treatment of a Si(001) substrate with phosphine (PH₃) gas at 80 Ton and 150° C. to form a new designer growth surface (hereafter denoted Si—Pₓ). Temperature programmed desorption (TPD) studies¹⁸ have shown that PH₃ undergoes a step-wise dissociative adsorption process on Si surfaces that culminates in the incorporation of P within Si—P surface dimers or P2 bridging dimers. We subjected these PH₃-treated Si substrates (FIGS. 1C) to the same MoS₂ growth conditions noted above and observed by SEM that the reaction produced a high-yield (˜75%) of nanoscale ribbon-like structures covering the substrate (FIGS. 7A-7E). High-resolution SEM imaging of individual structures reveals that they have greater than 10:1 aspect ratios and exceptionally uniform nanoscale widths along their length (FIG. 1E and FIGS. 8A-8C and FIG. 9). Raman spectra of these structures contain peaks at 383.7 cm⁻¹ and 407.6 cm⁻¹ that can be assigned to the characteristic MoS₂ E_{2g} intralayer shear and Ai_{g} breathing modes¹⁹, respectively (FIG. 10). AFM data collected over several line scans perpendicular to the long axis of a nanoribbon reveal a ˜1 nm height, and an AFM topographical map of a single nanoribbon shows its significant surface and height uniformity (FIG. 1F). This height is similar to previously reported heights of —0.8 nm for an as-grown single layer of MoS₂ on SiO₂²⁰. SEM data show that the crystals have an average width and length of 155 nm and 2.5 μm, respectively, (FIGS. 8A-8C) and no preferred orientation (FIGS. 7A-7E), which suggests that the crystals are not in crystallographic registry with the underlying surface. Moreover, we do not observe directed growth of MoS₂ crystals on PH₃-treated SiO₂ substrates (FIG. 11) which further reinforces the unique role of the Si—Pₓ surface in producing directed growth of MoS₂ crystals. Finally, we also show the synthesis of MoSe₂, WS₂ and WSe₂ crystals on Si—Pₓ substrates (Methods and FIGS. 12A-12C, 13A, 13B, 14A, 14B).

To show the versatility of our method according to some embodiments of the current invention, we demonstrated explicit synthetic tuning of the nanoribbon width over nearly 1-order of magnitude. Widths of the MoS₂ nanoribbons were systematically controlled by varying the total PH₃ dosage (in mL) during the Si(001) surface treatment step (Methods). Crystalline nanoribbons with average widths of 50 nm, 155 nm, and 430 nm were obtained when grown on Si(001) substrates treated with PH₃ dosages of 26 mL, 60 mL, and 120 mL, respectively (FIG. 1G and FIGS. 8A-8C). These data establish a distinct synthetic variable responsible for tuning crystal width and show that MoS₂ nanoribbons as narrow as 50 nm are readily attainable through our directed synthesis method.

Hereafter, we will refer to our material as 1D MoS₂ to reflect its significantly reduced dimension in one of the in-plane directions of the SiₓP_{y} substrate and to distinguish it from planar 2D MoS₂. Our results represent the first demonstration of a substrate-guided CVD growth of TMD crystals with restricted dimensionality. Recent work demonstrated the vapor-liquid-solid growth of MoS₂ ribbons from Na-containing catalyst droplets²¹. Previous work used vapor-solid processes in CVD reactors to realize the growth of vertically aligned MoS₂ crystals and nanobelts²²′²³. A recent report on the production of phosphorene nanoribbons through a Li-ion intercalation process reinforces the significant and growing interest in preparation of TMD materials with reduced dimensionality²⁴. Our substrate-mediated method represents a unique approach towards the production of horizontally aligned 1D MoS₂ crystals that are highly uniform and nanoscale in size.

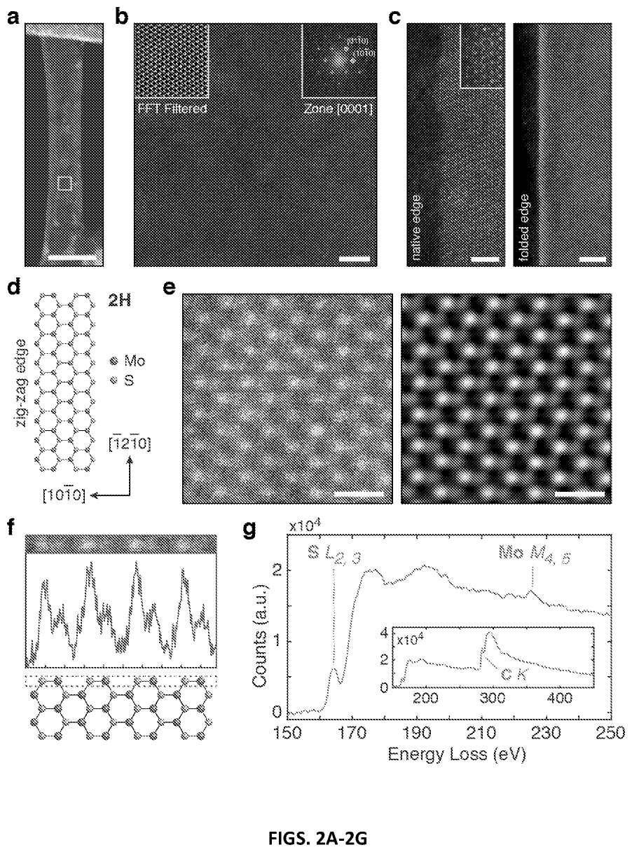

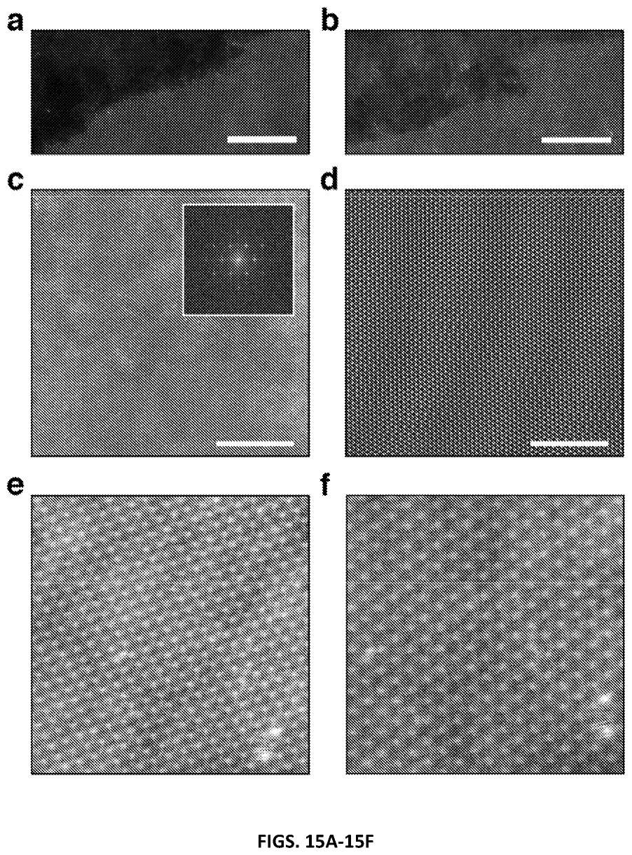

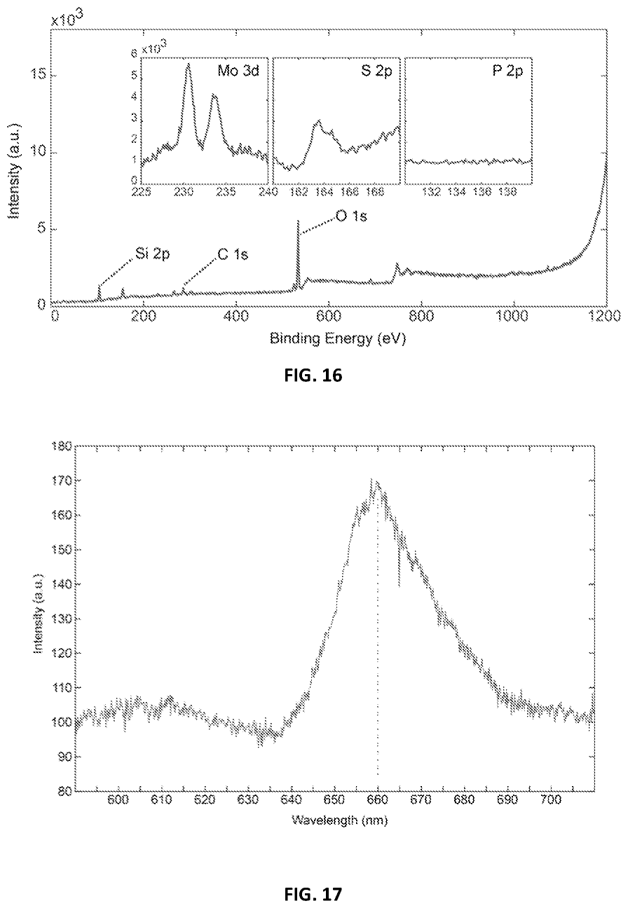

To ascertain the structure, composition, and quality of the 1D MoS₂ crystals, we performed aberration-corrected scanning transmission electron microscopy (ac-STEM) (FIGS. 2A-2G). Following their exfoliation from growth substrates, intact 1D crystals were transferred to TEM grids (FIG. 2A) and imaged at 60 kV in a Nion UltraSTEM™. Raw and Fourier-filtered high-resolution ac-STEM data were collected from a large region of a transferred crystal (FIG. 2A, boxed region) and from several regions within other crystal samples. These data reveal a crystalline lattice with few discernable atomic vacancies or line defects (FIG. 2B and FIGS. 15A-15F). The corresponding Fourier transform of the raw lattice data is consistent with the hexagonal reciprocal lattice pattern of MoS₂ when taken along the <0001> zone axis (FIG. 2B inset) and can be used to index the longitudinal axis of the crystal to the <1210> direction²⁵. Further analysis of the periphery of the transferred crystal reveals several distinct features (FIG. 2C and FIGS. 15A-15F). First, the unfolded long edges of the 1D crystal are largely straight, have the zig-zag configuration, and exhibit occasional random spatial deviations up to 3 nm. This edge quality compares favorably with the edge structure reported for 2D MoS₂¹³, and is comparable to the high edge quality obtained in graphene nanoribbons prepared through lithography and gas phase etching²⁶. Second, folded regions of the crystal present abrupt and straight edges with visible Moire interference patterns in the regions where the lattice overlaps with itself. Together, these data permit assignment of the longitudinal axis of the 1D crystal to the <1210> direction and the transverse axis in the direction of the zig-zag edges to the <1010> direction (FIG. 2D). Raw and Fourier-filtered atomic resolution images reveal a periodic hexagonal pattern of high-angle annular dark field (HAADF) intensity across the crystal lattice (FIG. 2E). Integration of the HAADF intensity across a row of atoms along the <1010>direction within this lattice region reveals a —2:1 intensity ratio for constituent atomic pairs (FIG. 2F). The pattern and relative magnitude of HAADF intensity variations in these data are consistent with Z-contrast signal arising from the 2H phase of MoS₂²⁷. Finally, electron energy loss spectroscopy (EELS) identifies two features at 164 eV and 225 eV that can be ascribed to energy losses²⁸ associated with the S L2,3 and Mo M_{4,5} major ionization edges, respectively (FIG. 2G). Neither these EELS data nor X-ray photoelectron spectra (XPS) contain signals ascribable to P (FIG. 16). Results of further STEM analyses on other transferred crystals confirm our finding that the 1D crystals are composed of high quality crystalline 2H phase MoS₂ with abrupt edges (FIGS. 15A-15F).

FIGS. 2A-2G show aberration-corrected scanning transmission electron microscopy and spectroscopy of 1D MoS₂ nanocrystals according to an embodiment of the current invention. FIG. 2A, shows low-magnification STEM image of a 1D MoS₂ crystal suspended over a hole on a TEM grid. The modest curvature in the profile of the 1D crystal is a simple consequence of the natural folding of its flexible edges during exfoliation and transfer. The scale bar is 100 nm. FIG. 2B shows a HAADF-STEM image taken within the yellow boxed region highlighted in (FIG. 2A). Insets: FFT filtered image of the raw lattice data encompassed by the inset (left); FFT of the raw lattice data shown in this panel (right). The scale bar is 2 nm. FIG. 2C shows HAADF-STEM images of an unfolded (native) edge (left) and folded edge (right) of the 1D MoS₂ crystal. Inset: Zoomed-in view of unfolded edge region revealing the zig-zag configuration of Mo and S atoms. The scale bars are 2 nm. FIG. 2D is a schematic identifying the principal crystallographic directions and zig-zag edges for a 1D MoS₂ crystal (zone axis: <0001> ). FIG. 2E shows raw (left) and FFT filtered (right) atomic resolution HAADF-STEM images of the 1D MoS₂ sample. The scale bar is 5 A. FIG. 2F shows a HAADF intensity line-scan across the row of atoms selected from the purple boxed region in (FIG. 2D). FIG. 2G shows an EELS spectrum collected on a 1D MoS₂ sample. Inset: EELS spectrum showing a wider range of the high-loss region. Dashed red lines are used to identify peaks of interest.

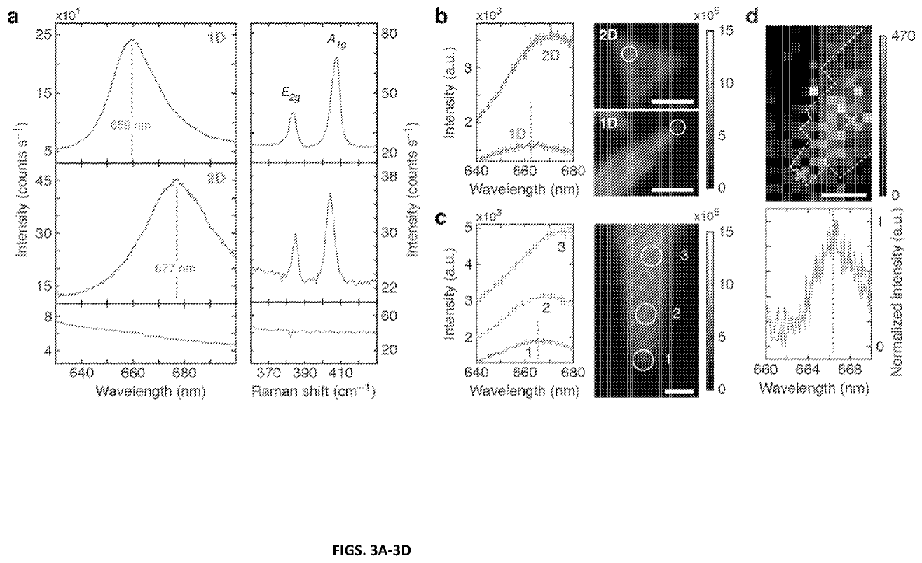

FIGS. 3A-3D show optical spectroscopy of 1D and tapered MoS₂ nanocrystals according to an embodiment of the current invention. FIG. 3A shows PL (left) and Raman (right) spectra of 1D and 2D MoS₂ crystals and of the Si—Pₓ substrate (orange). Dashed black lines are used to identify peak center wavelength. FIG. 3B shows PL spectra (left) collected from the white circled regions in the corresponding PL maps (right) of 1D and 2D MoS₂ crystals. Shaded bar defines PL intensity for both far-field PL maps. The scale bars are 2 μm. FIG. 3C shows PL spectra (left) collected from the 3 white circled regions in the corresponding PL map (right) of a tapered 1D MoS₂ crystal. Shaded bar defines PL intensity for the far-field PL map. The scale bar is 1 μL data were collected for green laser excitation. White circle diameters correspond to the laser spot size. FIG. 3D shows Top: Near-field PL map of the tip region of the tapered 1D MoS₂ crystal. Shaded bar defines PL intensity for the near-field PL map. Bottom: Near-field spectra collected from the edge (darker) and the interior (lighter) of the 1D crystal. The two spectra were collected from the edge and interior spots denoted by the darker and lighter crosses in the map, respectively. The spatial resolution is —20 nm. The outline of the 1D MoS₂ crystal is highlighted by the dashed white line. The scale bar is 100 nm.

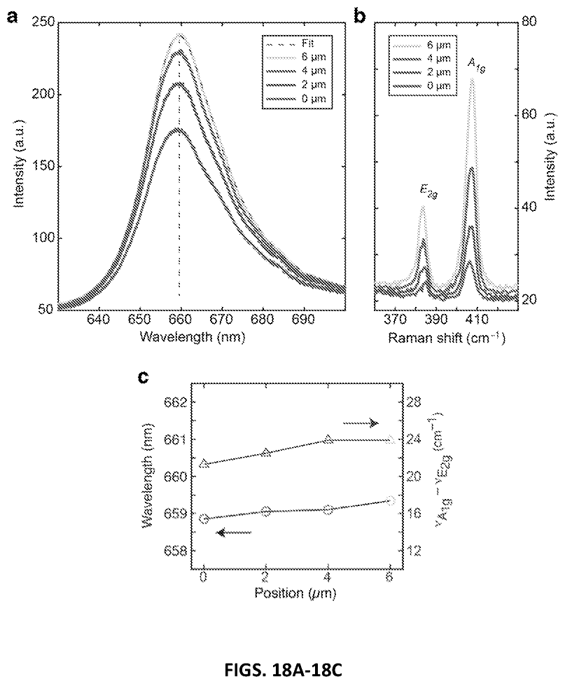

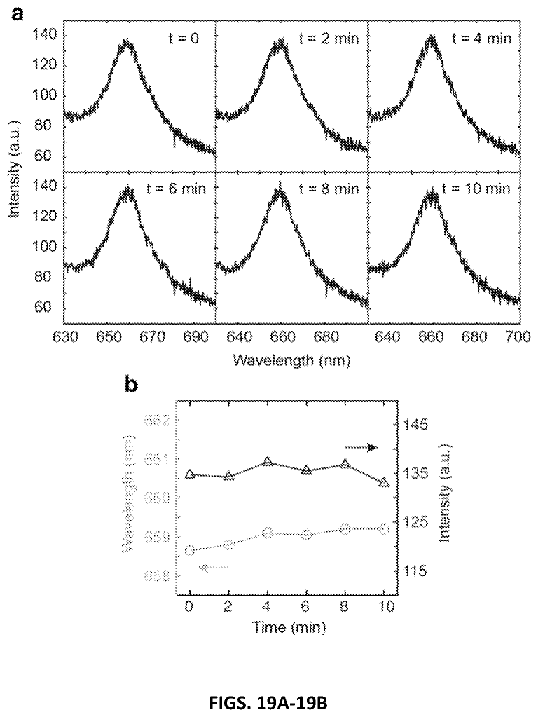

We next examined the influence of dimensionality on the optical properties of 1D MoS₂ crystals. The photoluminescence (PL) spectrum collected at room temperature and ambient pressure from a 1D crystal residing on its Si—Pₓ growth substrate exhibits a pronounced peak at 659 nm (FIG. 3A top). A Raman spectrum collected at the same point contains peaks centered at 383.7 and 407.6 cm⁻¹. These peaks are characteristic of the E_{2g} and A_{1g} modes, respectively, of MoS₂, and the 23.9 cm⁻¹ difference between them suggests that the specimen under investigation comprises ˜4 layers¹⁹. A neat Si—Pₓ substrate shows no PL or Raman signatures within the spectral regions considered above (FIG. 3A bottom). Notably, a single-layer 1D crystal has a PL peak wavelength of 658.6 nm, which is within 0.1% of the PL peak wavelength of the aforementioned multi-layer 1D crystal (FIG. 17). In addition to this negligible change in PL energy with increasing layer number, we note that the PL does not exhibit the significant attenuation in intensity normally observed in 2D TMD crystals with increasing layer number²⁹⁻³¹. Spectra collected at 4 independent positions on a growth substrate containing 1D crystals each reveal PL with peak wavelengths, which are consistent with those of a 1D crystal and vary by less than 0.08% (FIGS. 18A-18C). Moreover, spectra continuously recorded over a 10 min period at a fixed point on a 1D crystal show that its PL exhibits a less than 0.09% and less than 3% variation in wavelength and intensity, respectively, over time (FIG. 19A, 19B). Finally, in comparison to the 1D crystal, the PL spectrum of a 2D MoS₂ crystal on SiO₂ exhibits a lower energy peak at 677 nm, and the 19.3 cm⁻¹ difference between its Eg_{g} and Ai_{g} Raman modes suggests the specimen is a single-layer crystal (FIG. 3A middle). Together, these data attest that 1D MoS₂ crystals exhibit PL that is robustly blue-shifted by 50 meV relative to that of 2D MoS₂ crystals.

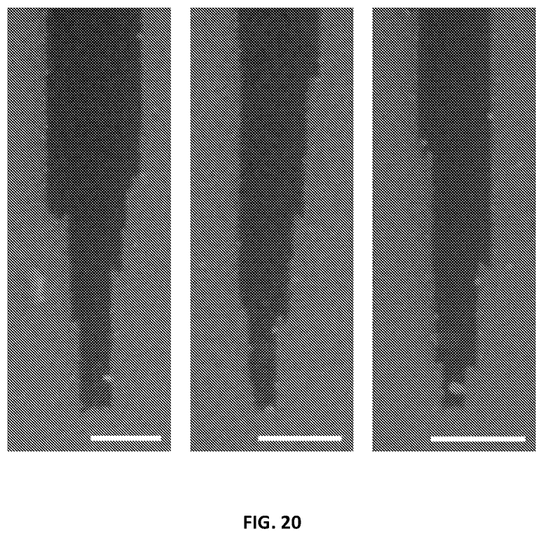

Notably, PL mapping of 1D MoS₂ crystals, which were transferred to SiO₂ substrates, identifies several important features (FIGS. 3B, 3C). First, the PL spectrum collected from 1D MoS₂ crystals on SiO₂ exhibits a peak at 661 nm, which is consistent with the PL peak wavelength observed for as grown 1D MoS₂ crystals on Si—Pₓ substrates (FIG. 3B). From these data we conclude that the observed blue-shift of PL for 1D MoS₂ crystals is not substrate induced. To further assess the morphology-dependent optical properties of our material, we synthesized 1D MoS₂ crystals with tapered profiles (FIG. 20). PL spectra acquired from 3 progressively narrower regions of a tapered 1D crystal on SiO₂ reveal a monotonic shift of the PL peak wavelength to shorter wavelengths as crystal width decreases from approximately 1500 nm to 400 nm (FIG. 3C). Near-field PL spectra collected from 20 nm×20 nm areas at the edge and interior of the tapered 1D crystal show no significant difference in emission wavelength (FIG. 3D). A previous study with nano-optical probes showed that exciton relaxation near disordered edges is responsible for —150 nm wide exciton-quenching regions located at the periphery of 2D MoS₂ crystals³². The uniformity of the PL energy across the <200 nm wide region of our tapered 1D crystal may be explained by its width falling entirely within the span of the aforementioned edge-boundary exciton quenching region. Moreover, the monotonic blue-shift of the PL spectrum of the tapered 1D crystal (FIG. 3C) may reflect a steady shift of its spectral median³² to higher energies as the contribution of other emitting pathways is reduced with decreasing crystal width. These data demonstrate that the PL emission energy in 1D crystals can be tuned through synthetic control of the crystal width.

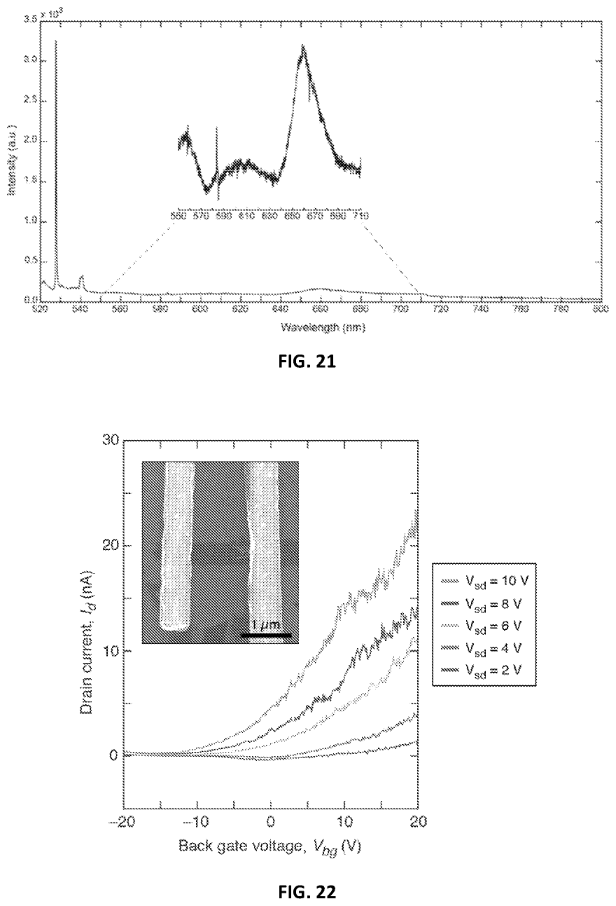

The foregoing results highlight that the unique PL properties of 1D MoS₂ crystals arise from their restricted dimensionality and are tunable through their width. The dominant PL feature (FIG. 21) of the 1D crystals at 1.87 eV (659 nm) may be ascribed to emission arising from the band-edge transition at the K-point in MoS₂³³. This emission is 50 meV higher in energy than the 1.82 eV transition typically observed in 2D MoS₂ crystals on SiO₂^{29,34}. Phase differences are unlikely the cause of the blue-shift, because STEM data have identified that the crystals occupy the known semiconducting 2H phase. Measurements of the current as a function of back gate voltage (I_{sd}-Vb_{g}) for a 1D MoS₂ crystal field effect transistor (FET) device reveal typical n-type transfer characteristics (FIG. 22). Although it is known that emission from the neutral A exciton or negatively charged A⁻ trion can shift in response to the crystal dielectric environment and charge transfer doping from the substrate³⁴⁻³⁶, we discount these effects as the cause of the blue-shift, because our PL data show a consistent PL response from 1D crystals on both Si—Pₓ and SiO₂ substrates. Finally, though our data suggest that our 1D nanoribbons are of high crystal quality, we cannot rule out the possibility that strain and edge states contribute to shifting the optical properties of these dimensionally restricted materials³⁷.

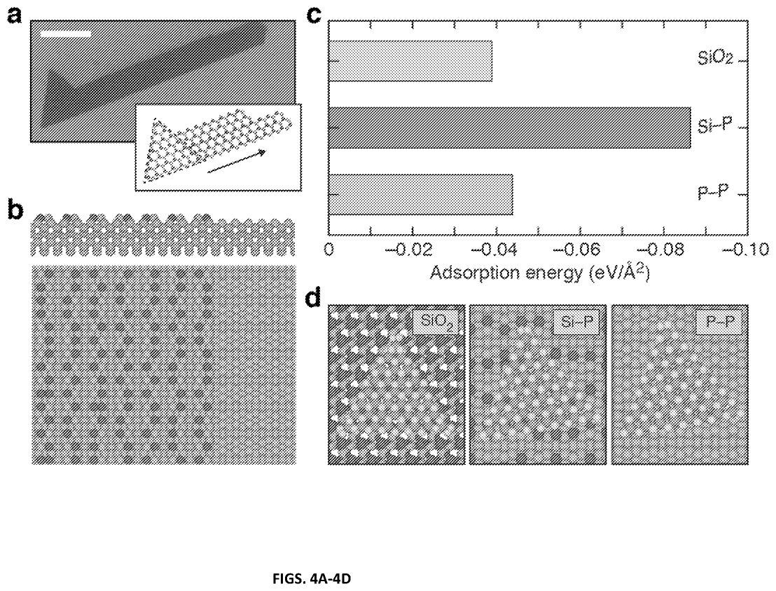

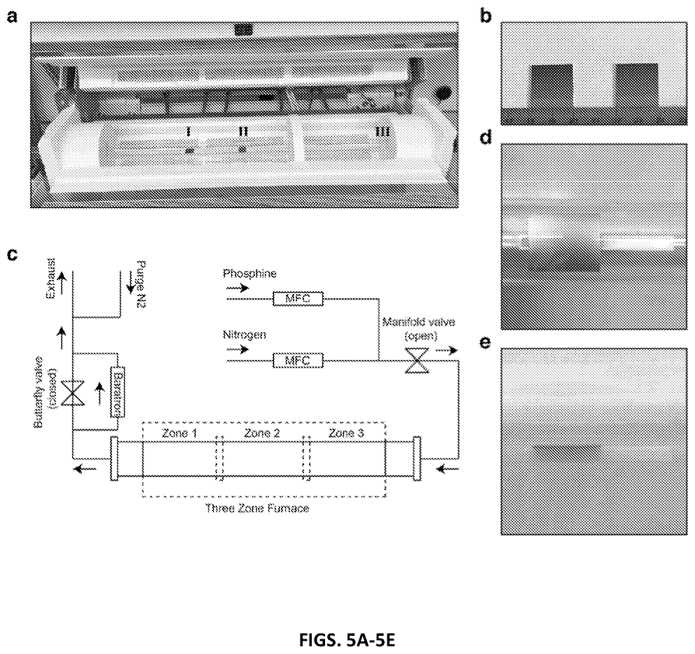

FIGS. 4A-4D show experimental and computational support for a proposed mechanism for 1D MoS₂ nanocrystal growth according to an embodiment of the current invention. FIG. 4A shows a high-resolution SEM image visualizing the early stage of 1D MoS₂ crystal growth. The scale bar is 500 nm. The inset is a schematic depicting growth of a 1D crystal from one of the edges of a nanoscale 2D crystal “seed”. FIG. 4B shows side and top views of a representative Monte Carlo snapshot of the Si—Pₓ surface in equilibrium at 150° C. and a PH₃ partial pressure of 8 Ton. Dark and light spheres correspond to Si and P atoms in surface dimers, respectively. Si atoms not on the surface are denoted as grey spheres. FIG. 4C shows DFT-calculated adsorption energy between an incipient MoS₂ crystal (modeled as 126-atom test particle) and a P—P dimer covered surface, a Si—P dimer covered surface, and an a— quartz(001) surface modeling SiO₂. More negative energies indicate stronger interaction. FIG. 4D shows 126-atom MoS₂ test particles adsorbed on SiO₂, Si—P and P—P surfaces.

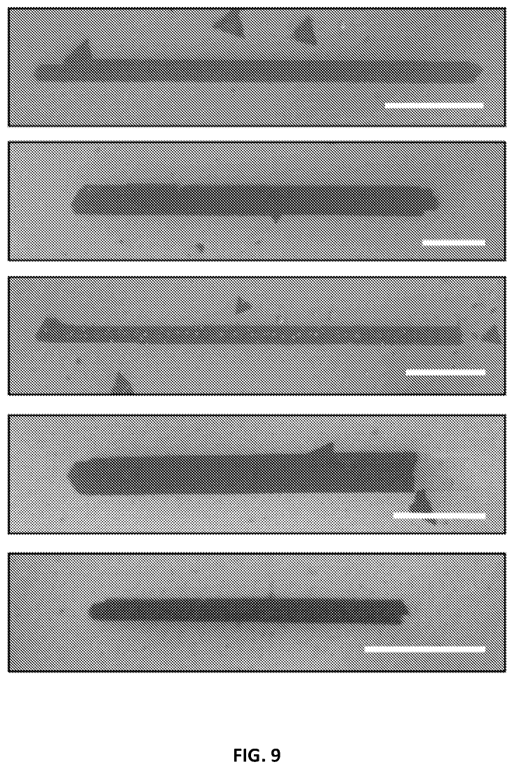

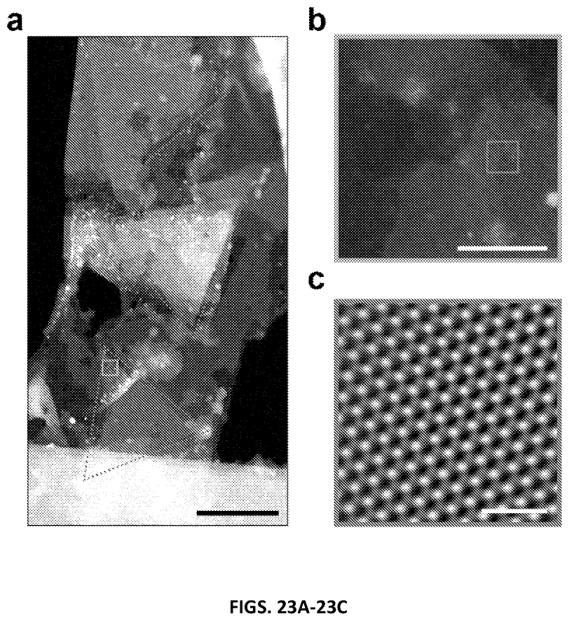

Finally, we sought to identify a possible mechanism for the observed directed growth of 1D crystals. An investigation of SEM images taken during the early stages of 1D crystal growth on Si—Pₓ surfaces revealed the presence of many nanoscale 2H phase 2D MoS₂ crystals with —200 nm edge lengths (FIGS. 23A-23C; FIGS. 7A-7C; FIG. 9). Notably, for MoS₂ growth on substrates dosed with 60 mL of PH₃, there was a strong correlation between the average edge length (190 nm) of the nanoscale 2D crystals and the average width (155 nm) of the resulting 1D crystals (FIG. 8C). Moreover, additional analyses found evidence for the apparent outgrowth of 1D crystals from one of the edges of the aforementioned nanoscale 2D crystals (FIG. 4A).

Together, these data suggest that 2D MoS₂ nanocrystals may serve as the “seeds” from which 1D crystal nucleation and growth takes place.

To assess whether the PH₃-treated surface plays a role in stabilizing the 2D MoS₂ nanocrystal “seeds”, we modeled not only the composition and order of the putative Si—Pₓ surface, but also interactions between this surface and incipient MoS₂ crystals (ie. the 2D “seeds”). As discussed above, the deposition of phosphine on the Si(001) surface has been shown to result in the formation of Si—P or P—P surface dimers that can arrange into elongated islands and terraces on the Si(001) surface^{18,38}. We believe it is unlikely that these extended islands and terraces guide the long-range growth of MoS₂ crystals, because while these surface features are oriented with respect to the underlying crystal lattice, the observed 1D MoS₂ nanocrystals show no specific orientation with respect to their growth substrate (FIGS. 7A-7E). An alternative explanation is that the coarsened topography of the Si—Pₓ surface induces symmetry breaking of incipient MoS₂ crystal nuclei and enables rapid crystal growth in one direction owing to the highly asymmetric energy landscape experienced by the crystal. To test this hypothesis, a representative structure for the PH₃-treated surface was generated by constructing a cluster expansion³⁹ of the Si—P surface and then performing Metropolis⁴⁰ Monte Carlo simulations (Methods). These simulations reveal that P preferentially segregates at the surface, resulting in a terraced structure predominantly terminated by Si—P and P—P dimers (FIG. 4B), in good agreement with experimental results^{18,38}. The sign of the effective cluster interaction for the dimer pair indicates that formation of Si—P dimers is favored, and this observation is also in good agreement with experiments³⁸. To estimate the strength of the interaction between MoS₂ and the treated Si surface, we calculated the energies of seven different orientations of a 126-atom MoS₂ test particle (a proxy for the nanoscale 2D “seed”) on one surface terminated with P—P dimers, one terminated with Si—P dimers, and one α—quartz(001) surface used to represent SiO₂ (FIGS. 4C, 4D). The average adsorption energy of the MoS₂ test particle on each of these surfaces is calculated to be —0.044 eV/A², —0.086 eV/A², and —0.039 eV/A², respectively (FIG. 4C). The foregoing analyses suggest that the relatively strong interaction between MoS₂ nuclei and the Si—P surface may explain the proliferation of stabilized nanoscale 2D “seed” crystals. The orientation of the edges of this “seed” relative to neighboring regions of the substrate on which MoS₂ growth is favored or disfavored may dictate the start of heterogeneous nucleation and subsequent asymmetric growth of 1D MoS₂ crystals. Detailed analysis of the configuration of the growth substrate and its role in defining 1D crystal growth will be the focus of future studies.

We have demonstrated that explicit synthetic manipulation of crystal morphology and dimensionality is a strategy for tuning the optical properties of TMD crystals and is unique in relation to the other methods used to induce changes in PL within TMD crystals, including with charge transfer salts⁴¹, strain engineering⁴², direct electrostatic gating¹¹, and substrate effect³⁴. This work highlights future opportunities for development of designer substrates that could mediate the synthesis of new low-dimensional crystals with prescribed structures and properties.

### Methods

CVD Reactor. Our home-built chemical vapor deposition (CVD) system is a versatile quartz tube hot-wall reactor design with a manifold of mass flow controllers (MKS Instruments: GM50A series MFCs) and a closed-loop pressure control system (MKS Instruments: 640B pressure controller). The manifold and pressure control circuit are both operated through custom LabView scripts running on a PC. The furnace (Thermo Scientific-Lindberg Blue M—3 zone) has 3 independently controllable zones, each of which measures 25 cm in length and can reach temperatures of 1200° C. A 400° C. temperature differential can be maintained between adjacent zones through the use of thermal inserts (FIG. 5A). A high-vacuum pump (Leybold: LV80 screw pump) is used to evacuate our CVD system to a base pressure of 0.01 mTorr and is able to safely manage toxic and pyrophoric effluent. The metal sealed GM50A series mass flow controllers on our CVD reactor permit highly accurate (1% setpoint accuracy) flow control and are accompanied by NIST traceable calibration sheets. Prior to all CVD reactions, we thoroughly washed and performed bake out of quartz tubes (Quartz Plus: 22 mm inner diameter, 25.4 mm outer diameter) at 500° C. for 2 hr under a 50 sccm N₂ flow.

Preparation of Si—Pₓ growth substrates through PH₃ treatment. Si wafers (Nova Electronic Materials: p-type <001>, 0.001-0.005 ohm-cm, 380±25 μm thick SSP prime grade Si wafers with 2 semi-standard flats and 2000 A±5% wet thermal oxide on both sides) were cut into individual substrates, each measuring 2 cm×2 cm. These substrates were rinsed with acetone and isopropyl alcohol and then cleaned by oxygen plasma treatment (Harrick Plasma) for 10 min at a P_{O2} of ˜650 mTorr and an RF power of 29.6 W. Substrates were then etched for 3 minutes in buffered hydrofluoric acid (Transene Company Inc: 10% Buffer HF Improved) to remove all SiO₂ (etch rate of SiO₂ in 10% BHF is ˜100 nm/min)⁴³.

After etching, these Si substrates were immediately loaded into the quartz tube of our CVD system and the system was evacuated to its base pressure of 0.01 mTorr within 10 min. Next, our reactor was flushed for 15 min under a constant 50 sccm flow of nitrogen (Airgas: 6N grade nitrogen with built-in-purifier). After this, N₂ flow was ceased and the reactor returned to base pressure within 2 min. Phosphine gas (Air Liquide: 10% PH₃ in He) was then introduced into the reactor at a flow rate of 20 sccm. The total reactor pressure was set to and subsequently maintained at 80 Ton for the duration of the reaction (P_{PH3}=8 Ton). The furnace temperature in all 3 zones was set to rise to 150° C. at a rate of 12.5° C./min. Once the furnace temperature reached 150° C., the reaction was allowed to proceed for 1 hr under a constant flow of PH₃. After 1 hr, the PH₃ flow was stopped and the reactor was evacuated to base pressure. The reactor was then cooled to room temperature within 10 min, thereby ending the PH₃ treatment reaction. For the experiments shown in FIG. 11, SiO₂ substrates (200 nm wet thermal SiO₂ on p-type Si) were exposed to the same treatment conditions described in this section.

Width control. Si(001) substrates were treated with total PH₃ gas dosages of 26 cm³, 60 cm³, and 120 cm³. The CVD reactor temperature was 150° C. The total PH₃ dose (cm³) was calculated using the expression for the partial volume of a gas in a mixture,

$${V}_{{PH}_{3}} = {V}_{Total} ( \frac{{P}_{{PH}_{3}}}{{P}_{Total}} ) ,$$

and the following table:

| | Total | | | | | Average |
|---|---|---|---|---|---|---|
| | reactor | PH₃ partial | Flow | | PH₃ | crystal |
| % PH₃ | pressure | pressure | rate | Time | dose | width, w |
| in He | (Torr) | (Torr) | (cm³/min) | (min) | (cm³) | (nm) |
| 10 | 80 | 8 | 20 | 60 | 120 | 430 |
| 10 | 80 | 8 | 10 | 60 | 60 | 155 |
| 20 | 20 | 4 | 10 | 13 | 26 | 50 |

Synthesis of 1D MoS₂ crystals. The PH₃ treated Si substrate from above was immediately loaded into a clean quartz tube containing molybdenum (VI) oxide (Strem Chemicals, 99.999%) and sulfur (Sigma-Aldrich). The solid precursors were contained within 2 alumina crucibles (MTI Corp: high purity 50 mm x 5 mm x 5 mm combustion boats) in the following quantities: (i) 0.015 g, 0.104 mmol molybdenum (VI) oxide in 1 crucible, (ii) 0.250 g, 8 mmol sulfur in 1 crucible. We controlled the position of the substrate and solid-phase precursors relative to each other and relative to the 3 heated zones of the furnace (FIGS. 5A-5E). The central furnace zone (held at 650° C. during the reaction) housed the substrate, which was placed face down over the crucible containing molybdenum (VI) oxide. The furnace zone upstream of the central zone (held at 250° C. during the reaction) housed the crucible containing sulfur. The reactor was subjected to 4 purge cycles, each of which consisted of flushing the reactor for 2 min under a 200 sccm flow of N₂. This purge process and evacuation to base pressure was complete within 15 min. After reaching base pressure, the flow rate of N₂ was changed to 20 sccm and the furnace temperature was increased from room temperature to 650° C. at a rate of 14° C./min. Once the furnace temperature reached 650° C., the reactor total pressure was set to 40 Ton and the reaction was allowed to proceed for 15 min at 650° C. and 40 Torr. After 15 min, the reactor was rapidly cooled to room temperature under a 200 sccm flow of N₂, thereby ending the MoS₂ reaction. For the experiments shown in FIG. 11, PH₃ treated SiO₂ substrates were placed downstream of the central furnace zone containing PH₃ treated Si substrates (this downstream zone was also held at 650° C. during the reaction) and were exposed to the same MoS₂ reaction conditions described in this section. This positioning of substrates and reagents is depicted in FIGS. 5A-5E.

Synthesis of MoSe₂, WS₂, and WSe₂ crystals. A detailed description of the synthesis of these crystals can be found with reference to Supplementary FIGS. 12A-12C, 13A, 13B, 14A and 14B.

Scanning Electron Microscopy. High resolution scanning electron micrographs were obtained on a Tescan Mira3 GMU SEM equipped with a field emission gun and Octane Plus silicon drift detectors for energy dispersive x-ray spectroscopy (EDS) analysis. ImageJ and MATLAB were used to perform statistical analyses of the SEM images of 1D MoS₂ crystals in order to extract information on their yield, dimension, aspect ratio, and in-plane orientation.

Atomic Force Microscopy. The height and topography of the 1D and 2D MoS₂ nanocrystals was measured on a Keysight 5500 atomic force microscope (AFM) using an Al-coated Si probe tip (TAP190AL-G-10). AFM imaging was carried out in non-contact mode in order to prevent damage to and unintentional displacement of the atomically thin crystals during scanning. AFM raw images (.mi) were processed in Gwyddion 2.51. A second-order polynomial correction was applied to subtract background noise in the raw image. A 3-point leveling with an averaging radius of 5 pixels was applied to correct for a linear offset across the whole image.

X-ray Photoelectron Spectroscopy (XPS). A sample of as-grown 1D MoS₂ crystals was analyzed in a PHI 5600 system under ultra-high vacuum conditions (<10⁻⁸ Ton). A Mg-Ka source (1253.6 eV) operated at 300 W and 15 kV was used to generate X-rays. The kinetic energy (in eV) of the ejected photoelectrons was measured using a hemispherical energy analyzer operating at a constant pass energy of 58.7 eV. The spot-size of the incident X-ray beam was 0.8 mm×2.0 mm. The step-size of the measurement was 0.125 eV. The characteristic X-ray emission lines shown in FIG. 16 are in accordance with literature values⁴⁴. The relative atom % concentration of the constituent elements was analyzed by taking into account the atomic sensitivity factors (ASF) for the X-ray source inclined at 54.7°.

Transfer of 1D MoS₂ crystals to TEM grids. 1D MoS₂ crystals grown on PH₃ treated Si substrates were transferred to TEM grids as follows. Spin coating (spin speed: 2500 rpm; spin time: 60 s; acceleration time: 5s) was used to deposit a layer of poly (methyl methacrylate) (PMMA) (Sigma-Aldrich: MW ˜996,000) over the 1D MoS₂ crystals residing on their Si—Pₓ growth substrates. The PMMA coated sample was then baked at 135° C. for 15 min and then transferred face-up onto the surface of a 1 M KOH solution. The solution was heated to and maintained at a temperature of 60° C. After —2 hr, complete etching by KOH of the underlying Si substrate allowed the PMMA film to delaminate and float on the surface of the solution. Most of the 1D MoS₂ crystals remained adhered to the PMMA film. The delaminated PMMA film was washed several times with de-ionized (DI) water by transferring it between beakers of DI water. After this, the PMMA film was extracted onto the surface of a TEM specimen support grid (Quantifoil substrate: 658-300-AU, Ted-Pella Inc.) by holding the grid with a pair of fine inversion tweezers and using it to gather the floating PMMA film onto it. The TEM grid sample was allowed to dry in air. Special care must be taken during the extraction step so as to minimize damage to the atomically thin 1D MoS₂ crystals. Finally, the TEM grid was placed in a furnace and annealed at 450° C. for 4 hr under an Ar atmosphere. This step is effective at removing PMMA without distorting the original morphology of the MoS₂ crystals.

Aberration-Corrected (Cs) Scanning Transmission Electron Microscopy (STEM). Prior to Cs-STEM characterisation, TEM grids were transferred to sample cartridges and then baked in vacuum (<1×10⁻⁶ Ton) at 120° C. for 14 hr. Afterwards, the sample cartridges were transferred to the microscope column with less than 1 min exposure to ambient conditions. The Cs-STEM (Nion, UltraSTEM-200X) was first aligned and then aberrations were removed using a ‘standard’ sample of gold evaporated on carbon. After this alignment and Cs-correction step, the TEM grids containing 1D MoS₂ crystals were inserted into the column for imaging. All images were collected using the microscope's high-angle annular dark-field (HAADF) detector with the microscope operating at 60 kV with correction taken to 5^{th} order and 60 mrad. The STEM probe size was 130 pm. Shear transformation for FIG. 15F was performed by first estimating the coarse drift through measurement of the distortion in the FFT pattern. Further refinement of the shear transformation matrix was performed by minimizing the variance in the distances of the most intense FFT spots as obtained through iterative application of different affine transformations.

Raman and Photoluminescence Spectroscopy. Micro-Raman scattering measurements were collected in a backscattering geometry using a Horiba Jobin Yvon T46000 spectrometer equipped with a liquid-N₂ cooled charge coupled device (CCD) detector in a single monochromator configuration. The excitation source was an Ar⁺/Kr⁻ coherent laser operating at 514 nm and a laser power of 1 mW. A 50x objective lens was used. The laser probe size was ˜2 μm. Raman spectra in the range 200-800 cm⁻¹ were obtained using a spectral resolution of 2 cm⁻¹. Photoluminescence (PL) spectra in the range 500-800 nm were obtained with a spectral resolution of 0.2 nm. Horiba's proprietary DuoScan™ system was operated in stepper mode in order to map Raman and PL intensities within an area of interest encompassing less than 10 μm×10 μm. Using this acquisition mode, the laser probe size and spatial resolution were ˜1 μm and the spectral resolution was 1 nm. Time dependent measurements were also carried out using the DuoScan™ system. All measurements were performed at room temperature and ambient pressure. Peak positions were extracted from gaussian fits to the raw PL data performed in MATLAB.

2D Micro-Photoluminescence mapping. Micro-PL measurements were conducted on 1D MoS₂ crystals, which were transferred to SiO₂ on Si substrates using the protocol described in ‘Transfer of 1D MoS₂ crystals to TEM grids’ above. The samples were scanned with a continuous-wave (CW) green laser (z1=532 nm) whose position over the sample was precisely controlled by a dual axis scanning galvo system (Thorlabs). The PL signal was collected by a 100× objective lens (N.A.=0.90). The pump laser was excluded from the PL signal by a 532 nm high pass filter. The collected PL signal was focused onto a single-mode fiber. A 50:50 fiber beam splitter was used to direct the fiber-coupled light either to a spectrometer (Princeton Instruments, Acton SP2500) with a 300 g/mm grating and silicon CCD or to the avalanche photodiode (APD). PL spectra were integrated over 5 min.

Near-field Photoluminescence mapping. Near-field photoluminescence mapping was performed using an OmegaScope-R SPM (AIST-NT, now Horiba Scientific) coupled with a LabRAM HR Evolution Raman Spectrometer (Horiba Scientific). A Ag-coated OMNI-TERS probe covered by a protective layer (Horiba Scientific) was employed for near-field PL imaging. The samples were scanned with a laser, λ_{excitation}×633 nm, and the power on the tip was maintained at —500 μW. The PL map (FIG. 3D, top) was obtained using a grating with 100 lines/mm and an integration time of 1 s per pixel. The PL spectra (FIG. 3D, bottom) were obtained using a grating with 600 lines/mm and an integration time of 5 min.

Device Preparation and Characterisation. Crystal Transfer. 1D MoS₂ crystals were transferred to SiO_{2/}Si substrates as follows. A PMMA (C6 resist, MicroChem Corp.) layer was deposited onto a Si substrate containing as-grown 1D MoS₂ crystals by spin-coating at 4000 rpm for 40 s. The crystals were released from the Si substrate by etching in KOH solution for several hours at 70° C. The 1D MoS₂ crystals stay adhered to the PMMA film as it floats on the surface of the KOH solution. This PMMA film with attached crystals was transferred to a dish of DI water for rinsing, then transferred again to the device substrate (SiO₂/Si) and finally completely dried. Once dry, the PMMA layer was selectively removed by dipping the device substrate in acetone for 10 min.

Field Effect Transistor (FET) Fabrication. Electrical contacts (Ti (adhesion layer): 5 nm; Au (contact layer): 50 nm) were patterned over the 1D crystals by electron-beam lithography and then deposited through thermal evaporation. First, a PMMA (C6) layer was deposited over the device substrates containing the 1D crystals by spin-coating at 4000 rpm for 40 s. The resists were subjected to baking at 280° C. for 150 s after the coating step. The contact patterns were defined by electron-beam lithography (JEOL JSF-7001F) followed by resist development and rinsing in MIBK and IPA for 90 s and 30 s, respectively. A 5 nm thick Ti adhesion layer followed by a 50 nm thick Au layer was deposited by thermal evaporation. Residual metal lift-off was performed in acetone over 10 min.

Transistor Property Measurement. The fabricated FET devices were mounted to a xy-translation stage, which is part of our home-built device characterisation microprobe station. The substrate back-side gate electrode was connected using silver paste. The devices were connected via Au-plated W probes and triax cables to an ultra-low noise semiconductor parameter analyzer (Agilent 4156C). The device drain current was recorded as a function of the applied back-side gate voltage.

Theory. Cluster expansion. Cluster expansions are generalized Ising models that account for many-body interactions³⁹ and are used here to predict the equilibrium structure of Si—Pₓ surfaces. For the slabs in this study, we assume each site can be occupied by either a Si/P atom, or a vacancy (only in the outmost layer) based on the (1×2) dimer-reconstructed cell, as it is known that dimers are formed on the Si(001) surface'. The cluster expansion allows for the incorporation of P atoms in the Si surface, their penetration into deeper layers, and the formation of surface defects. We fit the cluster expansion to a set of training structures calculated using density functional theory (DFT)⁴⁵ using a Bayesian method which improves the predictive accuracy of the cluster expansion⁴⁶. The training set contains randomly generated structures with varying P and vacancy concentrations. Ground-state structures predicted by the cluster expansion were added back to the training set to improve the quality of the cluster expansion.

For this cluster expansion, a total of 114 structures are in the training set, and the root mean square leave-one-out cross-validation (LOO CV) error is 5.4 meV/atom relative to DFT.

DFT. All DFT calculations were performed using the Vienna Ab initio Simulation Package (VASP)⁴⁷. For the Si—P-Vacancy cluster expansion, the revised Perdew-Burke-Ernzerhof (RPBE) ⁴⁸ exchange-correlation functional was used. For the calculations involving MoS₂, the PBE⁴⁹ functional with van der Waals dispersion correction was used (denoted as PBE-D3)⁵⁰, as it has been shown to provide more accurate energetics of MoS₂⁵¹. The Si_GW, P_GW, H_GW, O_GW, Mo_pv, and S_GW PBE projector-augmented wave (PAW) potentials⁵² were used, and all VASP calculations were run with accurate precision. For the Si—P-Vacancy training set structures, the Brillouin zone was sampled using grids generated by the k-point grid server⁵³ with a minimum distance of 20 A between real-space lattice points. Because of the size of the slabs used for MoS₂ adsorption calculations, only a single k-point at the center of the Brillouin zone was used. Gaussian smearing with a width of 0.05 eV was used, and the total energies were subsequently extrapolated to T=0. The convergence criteria for the electronic self-consistent iteration and the ionic relaxation loop were set to be 10⁻⁴ eV and 10⁻³ eV, respectively.

MoS₂ calculations. DFT calculations with MoS₂ edge lengths ranging 5-9 sulfur atoms were performed on three model slabs that consist of SiO₂(001), Si—P, and P—P dimers. The adsorption energy is:

E_{ads}=[E(slab+MoS₂)−E(slab)−E(MoS₂)]/A_{MoS}_{₂}

where E(slab+MoS₂) is the energy of the substrate with MoS₂ on top, E(slab) is the energy of the substrate, and E(MoS₂) is the energy of the MoS₂ crystal. By this definition, more negative values indicate stronger adsorption. For each of the model slabs, seven orientations of MoS₂ with respect to the underlying substrate (0°, 5°, 10°, 15°, 20°, 25°, and 30) were chosen and then averaged.

FIGS. 5A-5E show positions of substrates and reagents in the CVD reactor. FIG. 5A is a photograph identifying the positions of three crucibles (labelled I, II, III) in the quartz tube when running MoS₂ synthesis simultaneously on PH₃ treated Si and SiO₂ substrates. The left end of the quartz tube is the downstream end of the reactor. I and II contained MoO₃ powder. The PH₃ treated SiO₂ substrate was positioned above I and the PH₃ treated Si substrate was positioned above II. The distance between I and II is 5 cm. III contained sulfur powder which was positioned 25 cm upstream of II. This 25 cm distance ensures consistent sulfur vapor concentration across the growth substrates positioned above I and II. FIG. 5B shows growth substrates (area=2 cm²) before PH₃ treatment. FIG. 5C is a schematic of our hot-wall CVD system depicting the MFC manifold, 3-zone furnace, and closed-loop pressure control circuit. FIG. 5D, 5E show top and side views of the growth substrate, which is placed face-down on the alumina crucible containing MoO₃ powder.

FIGS. 6A-6F show characterization of 2D MoS₂ crystals on SiO₂. FIG. 6A shows a bright-field optical image of 2D MoS₂ crystals on SiO₂. The scale bar is 50 μm. FIG. 6B is a low magnification SEM image of the same sample. The scale bar is 200 μm. FIG. 6C is a high magnification SEM image and AFM height profile (see dashed white line in (FIG. 6D)) of one triangular 2D MoS₂ crystal. The scale bar is 5 μm. FIG. 6Dis a high magnification AFM map of a single layer 2D MoS₂ crystal. The height profile shown in (FIG. 6C) was collected from scans taken along the dashed white line. The scale bar is 5 μm. FIG. 6E shows Raman spectra collected from a single layer 2D MoS₂ crystal (lower peaks) and from bulk MoS₂ (higher peaks). Inset: Optical image taken during acquisition of Raman data. The scale bar is 4 μm. FIG. 6F shows photoluminescence spectra collected from a single layer 2D MoS₂ crystal (upper curve) and from bulk MoS₂ (lower curve).

FIGS. 7A-7E show yield and angular orientation of 1D MoS₂ crystals. FIG. 7A shows representative SEM images taken to determine the length and width dispersion of the 1D MoS₂ crystals with an average width of 155 nm (FIG. 8B). The scale bars are 10 μm. FIG. 7B is an SEM image used to assay the in-plane angular orientation and yield of the 1D MoS₂ crystals with 155 nm average width. The scale bar is 10 μm. FIG. 7C is an SEM image showing a 1D crystal with an in-plane angular orientation of 0° or 180° with respect to the reference axis (dashed white line). The scale bar is 500 nm. FIG. 7D is a histogram showing the distribution of orientations exhibited by the 155 nm average width 1D MoS₂ crystals. FIG. 7E is a pie chart displaying the 74% yield of the 155 nm average width 1D MoS₂ crystals. These representative data were obtained by assaying the SEM image in FIG. 7B.

FIGS. 8A-8C show width control of 1D MoS₂ crystals. FIG. 8A provides representative SEM images taken at low (top) and high (bottom) magnifications of 3 distinct 1D MoS₂ crystal samples synthesized on Si(001) substrates treated with 26 cm³ (left), 60 cm³ (middle), and 120 cm³ (right) of PH₃. These images, and several others like them, were used to measure the widths (shown in FIG. 1G) and lengths of 1D crystals within each of the 3 samples. Average crystal widths (wmean) for each sample are displayed above. Clearly discernable 1D MoS₂ crystals are highlighted in red boxes. Scale bars for sample with wₘₑₐₙ=50 nm: 1 μm (top), 100 nm (bottom). Scale bars for sample with wₘₑₐₙ =155 nm: 5 μm (top), 500 nm (bottom). The scale bars for sample with wₘₑₐₙ =430 nm: 10 μm (top), 1 μm (bottom). FIG. 8B shows plots of the width and length of 1D MoS₂ crystals having a sample average width of 155 nm. These crystals exhibit an aspect ratio greater than 10:1. FIG. 8C is a plot of the edge length of 50 nanoscale triangle 2D MoS₂ crystals, which grew on the same Si—P substrate that yielded 1D MoS₂ crystals with an average width of 155 nm. Measurements were taken from the middle SEM image in FIG. 8A. The average edge length for these 2D crystals is 190 nm, which correlates well with the average width of the 1D crystals grown on this substrate. We hypothesize that 1D crystals grow from these nanoscale 2D “seed” crystals.

FIG. 9 provides SEM images of 1D MoS₂ crystals. Representative SEM images taken at high magnification showing that the as-grown 1D MoS₂ crystals have significantly uniform widths along their length. The scale bars are 1 μm.

FIG. 10 is a Raman spectrum of 1D MoS₂. The Raman spectrum was acquired from 1D MoS₂ on its Si—Pₓ growth substrate. The data were acquired over 360 s.

FIG. 11 shows growth of MoS₂ on PH₃ treated SiO₂ substrates. SEM images showing that 1D MoS₂ crystals do not grow on PH₃ treated SiO₂ substrates. Scale bars, 10 μm.

FIGS. 12A-12C is an example of MoSe₂ crystals on PH₃-treated Si(001) substrate. FIG. 12A shows a comparison of Raman spectra collected from MoSe₂ crystals grown on a PH₃-treated Si(001) substrate (lower curve) and on a SiO₂ (upper curve) substrate. Inset: Optical images taken during acquisition of Raman data. These data confirm that the crystals grown on PH₃-treated Si(001) are MoSe₂. Scale bars, 5 μm. FIG. 12B is a representative low-magnification SEM image (left) showing the PH₃-treated Si(001) substrate after CVD growth of MoSe₂ crystals. The scale bar is 20 μm. Inset: Representative low-magnification optical image taken during acquisition of Raman data. High-magnification SEM image (right) showing nano-scale MoSe₂ ribbon-like crystals grown on PH₃-treated Si(001) substrate taken approximately within the boxed region highlighted in teal. The scale bar is 1 μm. FIG. 12C shows triangular MoSe₂ crystals grown on SiO₂. The scale bar is 20 μm.

Synthesis: Phosphine gas (Air Liquide: 20% PH₃ in He) was introduced into the reactor at a flow rate of 10 sccm. The total reactor pressure was set to and maintained at 40 Torr for the duration of the reaction. The furnace temperature in all 3 zones was set to rise to 150° C. at a rate of 12.5° C./min. Once the furnace temperature reached 150° C., the reaction was allowed to proceed for 1 hr under a constant flow of PH₃. After 1 hr, the PH₃ flow was stopped and the reactor was evacuated to base pressure. Alumina crucibles containing molybdenum (VI) oxide (Strem Chemicals, 99.999%) and selenium (Alfa Aesar, 325 mesh, 99.5% metals basis) were loaded into a clean quartz tube in the following quantities: (i) 0.01 g, 0.069 mmol molybdenum (VI) oxide in 1 crucible, (ii) 0.13 g, 1.65 mmol selenium in 1 crucible. After reaching base pressure, the flow rates of N₂ and H₂ were set to 8 sccm and 5 sccm, respectively. The furnace temperature in zones 1 and 2 was increased to 700° C. over the course of 20 min, while the temperature in zone 3 (Supplementary FIG. 1c) was maintained at 600° C. during the reaction. The reaction was allowed to proceed for 10 min with the reactor pressure held at 40 Torr. After an hour, the reactor was rapidly cooled to room temperature under a steady flow of N₂ and H_{2.}

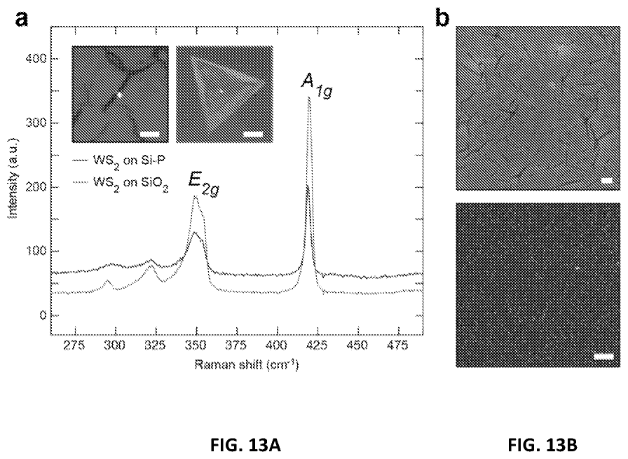

FIGS. 13A and 13B show W52 crystals on PH₃-treated Si(001) substrate. FIG. 13A is a comparison of Raman spectra collected from W52 crystals grown on a PH₃-treated Si(001) substrate (curve with lower peaks) and on a SiO₂ (curve with higher peaks) substrate. Inset: Optical images taken during acquisition of Raman data showing the significantly different morphology of the crystals grown on Si—P versus SiO₂. These data confirm that the ribbon-like crystals grown on PH₃-treated Si(001) are indeed W5₂. The scale bars are 5 μm. FIG. 13B provides representative SEM images showing the ribbon-like W52 crystals grown on PH₃-treated Si(001) (top) and the triangular W52 crystals grown on SiO₂ (bottom). The scale bars are 10 μm.

Synthesis: Phosphine gas (Air Liquide: 20% PH₃ in He) was introduced into the reactor at a flow rate of 20 sccm. The total reactor pressure was set to and maintained at 80 Torr for the duration of the reaction. The furnace temperature in all 3 zones was set to rise to 150° C. at a rate of 12.5° C./min. Once the furnace temperature reached 150° C., the reaction was allowed to proceed for 40 min under a constant flow of PH₃. After 40 min, the PH₃ flow was ceased and the reactor was evacuated to base pressure. Alumina crucibles containing tungsten (VI) oxide (Alfa Aesar, 99.8%) and sulfur (Sigma-Aldrich) were loaded into a clean quartz tube in the following quantities: (i) 0.01 g, 0.043 mmol tungsten (VI) oxide in 1 crucible, (ii) 0.4 g, 12.8 mmol sulfur in 1 crucible. After reaching base pressure, the flow rate of N₂ was set to 20 sccm and the furnace temperature was first increased to 600° C. in 30 min, and then to 800° C. in 20 min. Following these temperature ramps, the reaction was allowed to proceed for 10 min with the reactor pressure held at 40 Ton. After an hour, the reactor was rapidly cooled to room temperature under a 200 sccm flow of N₂.

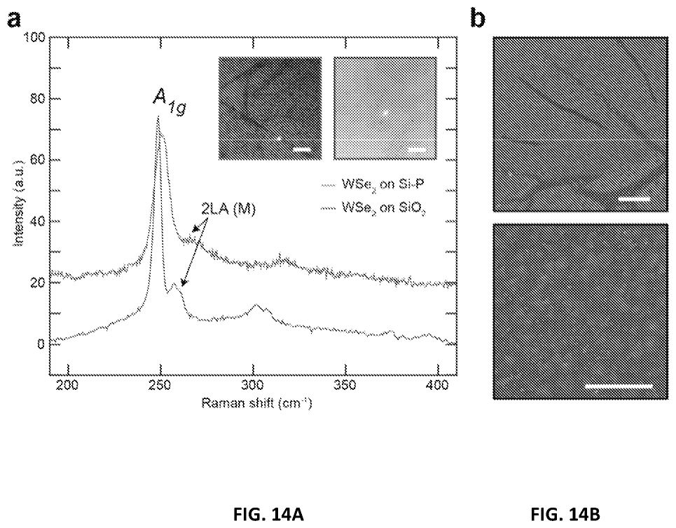

FIGS. 14A and 14B show WSe₂ crystals on PH₃-treated Si(001) substrate. FIG. 14A provides a comparison of Raman spectra collected from WSe₂ crystals grown on a PH₃-treated Si(001) substrate (upper curve, lower peak) and on a SiO₂ (lower curve) substrate. Inset: Optical images taken during acquisition of Raman data showing the significantly different morphology of the crystals grown on Si—P (upper curve, lower peak) versus SiO₂ (lower curve). These data confirm that the ribbon-like crystals grown on PH₃-treated Si(001) are WSe₂. The scale bars are 5 μm. FIG. 14B provide representative SEM images showing the ribbon-like WSe₂ crystals grown on PH₃-treated Si(001) (top) and the triangular WSe₂ crystals grown on SiO₂ (bottom). The scale bars are 10 μm.

Synthesis: Phosphine gas (Air Liquide: 20% PH₃ in He) was introduced into the reactor at a flow rate of 10 sccm. The total reactor pressure was set to and maintained at 20 Torr for the duration of the reaction. The furnace temperature in all 3 zones was set to rise to 150° C. at a rate of 12.5° C./min. Once the furnace temperature reached 150° C., the reaction was allowed to proceed for 1 hr under a constant flow of PH₃. After 1 hr, the PH₃ flow was stopped and the reactor was evacuated to base pressure. Alumina crucibles containing tungsten (VI) oxide (Alfa Aesar, 99.8%) and selenium (Alfa Aesar, 325 mesh, 99.5% metals basis) were loaded into a clean quartz tube in the following quantities: (i) 0.01 g, 0.043 mmol tungsten (VI) oxide in 1 crucible, (ii) 0.13 g, 1.65 mmol selenium in 1 crucible. After reaching base pressure, the flow rates of N₂ and H₂ were set to 8 sccm and 5 sccm, respectively. The furnace temperature was increased to 800° C. in 20 min, and the reaction was allowed to proceed for 10 min with the reactor pressure held at 20 Ton. After an hour, the reactor was rapidly cooled to room temperature under a steady flow of N₂ and H₂.

FIGS. 15A-15F show STEM-HAADF imaging of 1D MoS₂. FIG. 15A is a high-magnification STEM image showing the scalloped edge of a 1D MoS₂ crystal. The scale bar is 5 nm. FIG. 15B is a high-magnification STEM image showing the nearly atomically smooth interior edge of a 1D MoS₂ crystal. The scale bar is 5 nm. FIG. 15C is a large field-of-view (FOV) STEM image showing continuous MoS₂ crystal lattice. The inset is an FFT pattern of the raw lattice data. The scale bar is 5 nm. FIG. 15D is the same FOV as (FIG. 15C) after FFT filtering. The scale bar is 5 nm. FIG. 15E is an as-acquired STEM-HAADF with modest drift distortion. FIG. 15F is a similar ROI to that shown in (FIG. 15E) following affine transformation to correct shear and rotational distortion.

FIG. 16 shows an XPS analysis of 1D MoS₂. Full spectrum XPS scan (survey mode) collected from a sample of as-grown 1D MoS₂ crystals. Insets show selected scans (multi mode) of the Mo-3d, S-2p, and P-2p regions. Acquisition parameters for the survey mode: time per step =30 s, sweeps =2. Acquisition parameters for the multi mode: time per step =50 s, sweeps =10, with a constant pass energy of 58.7 eV. The Mo region shows spin orbit components 3d512 and 3d312 (energy spacing between components: —3 eV). The S-2p region shows a broad peak due to the two closely-spaced spin orbit components 2p312 and 2p112 (energy spacing between components: —1 eV). No characteristic lines were observed in the P-2p region. The relative atomic percentage (atom %) of the elements is shown below.

| Element | C 1s | Mo 3d | O 1s | P 2p | S 2p | Si 2p |
|---|---|---|---|---|---|---|
| atom % | 12.565 | 0.414 | 58.902 | 0.06 | 0.612 | 25.533 |

FIG. 17 is a PL spectrum of single layer 1D MoS₂. PL spectrum acquired from single layer thick 1D MoS₂ on its Si—P growth substrate. A PL peak at 660 nm is clearly visible and is consistent with the PL peak position observed for multi-layer 1D MoS₂ crystals (FIGS. 3A-3D). The data were acquired over 30 s.

FIGS. 18A-18C show position dependent PL and Raman spectra from 1D MoS₂. FIG. 18A shows PL spectra collected at 4 discrete points along a sample containing 1D MoS₂ crystals. Each PL spectrum was acquired over 360 s. The vertical dashed red line is associated with the PL peak position extracted from the Gaussian fit overlaid on the 6 μm PL data. FIG. 18B shows Raman spectra collected at the same 4 discrete points as in (FIG. 18A). Data acquisition time was 360 s, and the line scan step-size was 2 μm. FIG. 18C shows PL peak wavelength (left ordinate) and separation between Ai_{g} and Eg_{g} Raman active modes (right ordinate) as a function of position. Data are obtained directly from the data shown in panels (FIG. 18A) and (FIG. 18B).

FIGS. 19A-19B show time dependent PL spectra from 1D MoS₂. FIG. 19A shows PL spectra collected from 1D MoS₂ in 2 min increments over 10 min. The data acquisition time was 20 s. FIG. 19B shows PL peak wavelength (left ordinate) and corresponding PL intensity (right ordinate) as a function of time. The data are obtained directly from the data shown in panel (FIG. 19A).

FIG. 20 shows 1D MoS₂ crystals grown with tapered profiles. The SEM images of tapered 1D MoS₂ crystals. The scale bars are 500 nm.

FIG. 21 is a full-scale PL spectrum from 1D MoS₂. PL spectrum acquired from a sample of as-grown 1D MoS₂ crystals on their Si—Pₓ growth substrate. The weak and broad feature between 590 nm and 620 nm can be ascribed to the B exciton of MoS₂. Data acquisition time was 30 s.

FIG. 22 shows I-V characteristics of 1D MoS₂ crystal FET device. Drain current as a function of back-gate voltage (I-V_{bg}) for a 1D MoS₂ crystal field-effect transistor (FET) device. The five I_{d}-V_{bg} transfer characteristics were obtained for source-drain biases (Vsd) of 2, 4, 6, 8, and 10 V. Inset: High resolution SEM image of the 1D MoS₂ crystal FET device. Scale bar, 1 μm. The device was fabricated (Methods) after the crystals were transferred to SiO₂ on Si substrates.

FIGS. 23A-23C show STEM-HAADF imaging of nano-sized 2D MoS₂ “seed”. FIG. 23A is a low magnification STEM-HAADF image of a collection of nano-sized (edge length: —150 nm) triangular 2D MoS₂ crystals, which are proposed to be the “seeds” for growth of the 155 nm average width 1D MoS₂ crystals. Boundaries of the triangular 2D crystals are highlighted with dashed lines. The scale bar is 100 nm. FIG. 23B is a high magnification STEM-HAADF image of the boxed region in FIG. 23A that encompasses a portion of a nanoscale 2D crystal. The scale bar is 10 nm. FIG. 23C FFT-filtered high magnification STEM-HAADF image of the blue boxed region in FIG. 23B that encompasses a portion of the lattice of the nanoscale 2D crystal. The lattice pattern is consistent with the 2H phase of MoS₂. The scale bar is 1 nm.

### REFERENCES

1. Britnell, L. et al. Strong light-matter interactions in heterostructures of atomically thin films. Science 340, 1311-1314 (2013).
2. Voiry, D., Yang, J. & Chhowalla, M. Recent strategies for improving the catalytic activity of 2D TMD nanosheets toward the hydrogen evolution reaction. Adv. Mater. 28, 6197-6206 (2016).
3. Jaramillo, T. F. et al. Identification of active edge sites for electrochemical H₂ evolution from MoS₂ nanocatalysts. Science 317, 100-102 (2007).
4. Lee, C. H. et al. Atomically thin p-n junctions with van der Waals heterointerfaces. Nat. Nanotechnol. 9, 676-681 (2014).
5. Najmei, S. et al. Vapour phase growth and grain boundary structure of molybdenum disulfide atomic layers. Nat. Mater. 12, 754-759 (2013).
6. Geim, A. K. & Grigorieva, I. V. Van der Waals heterostructures. Nature 499, 419-425 (2013).
7. Tielrooij, K.-J. et al. Nano-imaging of intersubband transitions in van der Waals quantum wells. Nat. Nanotechnol. 13, 1035-1041 (2018).
8. Zhou, Y. et al. Revealing the contribution of individual factors to hydrogen evolution reaction catalytic activity. Adv. Mater. 30, 1706076:1-9 (2018).
9. Li, S. et al. Edge-enriched 2D MoS₂ thin films grown by chemical vapor deposition for enhanced catalytic performance. ACS Catal. 7, 877-886 (2017).
10. Blees, M. K. et al. Graphene kirigami. Nature 524, 204-207 (2015).
11. Wang, K. et al. Electrical control of charge carriers and excitons in atomically thin materials. Nat. Nanotechnol. 13, 128-132 (2018).
12. Unuchek, D. et al. Room-temperature electrical control of exciton flux in a van der Waals heterostructure. Nature 560, 340-344 (2018).
13. Shi, Y., Li, H. & Li, L. J. Recent advances in controlled synthesis of two-dimensional transition metal dichalcogenides via vapour deposition techniques. Chem. Soc. Rev. 44, 2744-2756 (2015).
14. Kang, K. et al. High-mobility three-atom-thick semiconducting films with wafer-scale homogeneity. Nature 520, 656-660 (2015).
15. Desai, S. B. et al. Gold-mediated exfoliation of ultralarge optoelectronically-perfect monolayers. Adv. Mat. 28, 4053-4058 (2016).
16. Zhang, X. et al. Diffusion-controlled epitaxy of large area coalesced WSe₂ monolayers on sapphire. Nano Lett. 18, 1049-1056 (2018).
17. van der Zande, A. M. et al. Grains and grain boundaries in highly crystalline monolayer molybdenum disulphide. Nat. Mater. 12, 554-561 (2013).
18. Cho, B. et al. Phosphorus incorporation during Si(001):P gas-source molecular beam epitaxy: Effects on growth kinetics and surface morphology. J. Appl. Phys. 103, 123530:1-10 (2008).
19. Lee, C. et al. Anomalous lattice vibrations of single- and few-layer MoS₂. ACS Nano 4, 2695-2700 (2010).
20. Gong, Y. et al. Tellurium-assisted low-temperature synthesis of MoS₂ and WS₂ monolayers. ACS Nano 9, 11658-11666 (2015).
21. Li, S. et al. Vapour-liquid-solid growth of monolayer MoS₂ nanoribbons. Nat. Mater. 17, 535-542 (2018).
22. Yang, L. et al. Single-crystal atomic-layered molybdenum disulfide nanobelts with high surface activity. ACS Nano 9, 6478-6483 (2015).
23. Kong, D. et al. Synthesis of MoS₂ and MoSe₂ films with vertically aligned layers. Nano Lett. 13, 1341-1347 (2013).
24. Watts, M. C. et al. Production of phosphorene nanoribbons. Nature 568, 216-220 (2019). 25. Wu, R. J., Odlyzko, M. L. & Mkhoyan, K. A. Determining the thickness of atomically thin MoS₂ and WS2 in the TEM. Ultramicroscopy 147, 8-20 (2014).
26. Wang, X. & Dai, H. Etching and narrowing of graphene from the edges. Nat. Chem. 2, 661-665 (2010).
27. Eda, G. et al. Coherent atomic and electronic heterostructures of single-layer MoS₂. ACS Nano 6, 7311-7317 (2012).
28. EELS Atlas Gatan: http://www.eels.info/atias
29. Splendiani, A. et al Emerging photoluminescence in monolayer MoS₂. Nano Lett. 10, 1271-1275 (2010).
30. Mak, K. F., Lee, C., Hone, J., Shan, J. & Heinz, T. F. Atomically thin MoS_{2:} A new direct-gap semiconductor. Phys. Rev. Lett. 105, 136805:1-4 (2010).
31. Duan, X. et al. Lateral epitaxial growth of two-dimensional layered semiconductor heterojunctions. Nat. Nanotechnol. 9, 1024-1030 (2014).
32. Bao, W. et al. Visualizing nanoscale excitonic relaxation properties of disordered edges and grain boundaries in monolayer molybdenum disulfide. Nat. Commun. 6, 7993:1-7 (2015).
33. Ataca, C., Sahin, H. & Ciraci, S. Stable, single-layer MX2 transition-metal oxides and dichalcogenides in a honeycomb-like structure. J. Phys. Chem. C 116, 8983-8999 (2012).
34. Scheuschner, N. et al. Photoluminescence of freestanding single- and few-layer MoS₂. Phys. Rev. B 89, 125406:1-6 (2014).
35. Mak, K. F. et al. Tightly bound trions in monolayer MoS₂. Nat. Mater. 12, 207-211 (2013).
36. Dubey, S. et al. Weakly trapped, charged, and free excitons in single-layer MoS₂ in the presence of defects, strain, and charged impurities. ACS Nano 11, 11206-11216 (2017).
37. Lin, Z. et al. Defect engineering of two-dimensional transition metal dichalcogenides. 2D Mater. 3, 022002:1-22 (2016).
38. Wang, Y., Chen, X & Hamers, R. J. Atomic-resolution study of overlayer formation and interfacial mixing in the interaction of phosphorous with Si(001). Phys. Rev. B 50, 4534-4547 (1994).
39. Sanchez, J. M., Ducastelle, F. & Gratias, D. Generalized cluster description of multicomponent systems. Phys. A 128, 334-350 (1984).
40. Metropolis, N., Rosenbluth, A. W., Rosenbluth, M. N., Teller, A. H. & Teller, E. Equation of state calculations by fast computing machines. J. Chem. Phys. 21, 1087-1092 (1953).
41. Mouri, S., Miyauchi, Y. & Matsuda, K. Tunable photoluminescence of monolayer MoS₂ via chemical doping. Nano Lett. 13, 5944-5948 (2013).
42. Castellanos-Gomez, A. et al. Local strain engineering in atomically thin MoS₂. Nano Lett.

13, 5361-5366 (2013).
43. Williams, K. R., Gupta, K. & Wasilik, M. Etch rates for micromachining processing — Part II. J. Microelectromech. Syst. 12, 761-778 (2003).
44. Ganta, D., Sinha, S. & Haasch, R. T. 2-D material molybdenum disulfide analyzed by XPS. Surf. Sci. Spectra 21, 19-27 (2014).
45. Kohn, W. & Sham, L. J. Self-consistent equations including exchange and correlation effects. Phys. Rev. 140, A1133-A1138 (1965).
46. Mueller, T. & Ceder, G. Bayesian approach to cluster expansions. Phys. Rev. B 80, 024103:1-13 (2009).
47. Kresse, G. & Hafner, J. Ab initio molecular dynamics for liquid metals. Phys. Rev. B 47, 558-561 (1993).
48. Hammer, B., Hansen, L. B. & Norskov, J. K. Improved adsorption energetics within density-functional theory using revised Perdew-Burke-Ernzerhof functionals. Phys. Rev. B 59, 7413-7421 (1999).
49. Perdew, J. P., Burke, K. & Ernzerhof, M. Generalized gradient approximation made simple. Phys. Rev. Lett. 77, 3865-3868 (1996).
50. Grimme, S., Antony, J., Ehrlich, S. & Krieg, H. A consistent and accurate ab initio parametrisation of density functional dispersion correction (DFT-D) for the 94 elements H-Pu. J. Chem. Phys. 132, 154104:1-19 (2010).
51. Reckien, W., Janetzko, F., Peintinger, M. F. & Bredow, T. Implementation of empirical dispersion corrections to density functional theory for periodic systems. J. Comput. Chem. 33, 2023-2031 (2012).
52. Blöchl, P. E. Projector augmented-wave method. Phys. Rev. B 50, 17953-17979 (1994).
53. Wisesa, P., McGill, K. A. & Mueller, T. Efficient generation of generalized Monkhorst-Pack grids through the use of informatics. Phys. Rev. B 93, 155109:1-10 (2016).

While various embodiments of the present invention have been described above, it should be understood that they have been presented by way of example only, and not limitation. Thus, the breadth and scope of the present invention should not be limited by any of the above-described illustrative embodiments, but should instead be defined only in accordance with the following claims and their equivalents.

The embodiments illustrated and discussed in this specification are intended only to teach those skilled in the art how to make and use the invention. In describing embodiments of the disclosure, specific terminology is employed for the sake of clarity. However, the disclosure is not intended to be limited to the specific terminology so selected. The above-described embodiments of the disclosure may be modified or varied, without departing from the invention, as appreciated by those skilled in the art in light of the above teachings. It is therefore to be understood that, within the scope of the claims and their equivalents, the invention may be practiced otherwise than as specifically described. For example, it is to be understood that the present disclosure contemplates that, to the extent possible, one or more features of any embodiment can be combined with one or more features of any other embodiment.

1. A method of producing transition-metal dichalcogenide crystals, comprising:
providing silicon substrate having a phosphine-treated surface;
exposing said phosphine-treated surface of said silicon substrate to a vapor containing a transition metal; and
exposing said phosphine-treated surface of said silicon substrate to a vapor containing a chalcogen,
wherein a crystal of said transition-metal and said chalcogen is formed on said phosphine-treated surface of said silicon substrate to produce a transition-metal dichalcogenide crystal by chemical vapor deposition.

2. The method of claim 1, wherein said transition-metal dichalcogenide crystal is a nano-ribbon structure.

3. The method of claim 1, wherein said phosphine-treated surface of said silicon substrate results from a Si(001) crystal surface that was treated with phosphine.

4. The method of claim 1, further comprising treating said silicon substrate to a dose of phosphine prior to said providing said silicon substrate.

5. The method of claim 4, wherein said dose of phosphine is at least 10 cm³ and less than 200 cm³.

6. The method of claim 4, wherein said dose of phosphine is at least 26 cm³ and less than 120 cm³.

7. The method of claim 5, wherein said phosphine-treated surface of said substrate is at least 5 cm² and less than 100 cm².

8. The method of claim 4, wherein said treating said silicon substrate to said dose of phosphine uses a gas mixture comprising phosphine and a noble gas.

9. The method of claim 8, wherein said noble gas is helium.

10. The method of claim 8, wherein said gas mixture consists essentially of at least 10% phosphine with the remainder being at least one noble gas.

11. The method of claim 5, wherein said dose of phosphine is selected for producing transition-metal dichalcogenide nanocrystal that is a nano-ribbon structure having a selected width.

12. The method of claim 1, wherein the transition metal is one of molybdenum and tungsten, and
wherein the chalcogen is one of sulfur and selenium.

13. The method of claim 4, wherein said treating said silicon substrate is performed at a temperature of at least 100° C. and less than 200° C.

14. The method of claim 4, wherein said treating said silicon substrate is performed at a temperature of at least 130° C. and less than 170° C.

15. The method of claim 4, wherein said treating said silicon substrate is performed at a temperature of about 150° C.

16. The method of claim 4, wherein said treating said silicon substrate is performed at a pressure of at least 5 Torr and less than 100 Torr.

17. The method of claim 4, wherein said treating said silicon substrate is performed at a pressure of about 80 Ton.

18. The method of claim 4, wherein said phosphine treated surface is a modified surface of a Si(001) crystal surface of a silicon substrate so as to have a surface composition containing Si and P in a stoichiometric proportion represent by SiₓP_{y} wherein x and y are each greater than 0 and less than 2 and subject to the constraint x+y=2.

19. The method according to claim 18, wherein x is at least 0.5 and less than 1 and y is at least 1 and less than about 1.5.

20. The method according to claim 18, wherein said phosphine treated surface of said silicon substrate comprises Si—P dimers.

21. A transition-metal dichalcogenide crystal produced according to the method of claim 1.

22. The transition-metal dichalcogenide crystal according to claim 21, wherein an edge of said transition-metal dichalcogenide crystal has a roughness less than 2 nm.

23. The transition-metal dichalcogenide nanocrystal according to claim 21, wherein said transition-metal dichalcogenide crystal is a nano-ribbon of one of MoS₂, MoSe₂, WS₂, WSe₂, or MoTe₂.

24. An electronic and/or opto-electronic device comprising a transition-metal dichalcogenide nanocrystal produced according to the method of claim 1.

25. The electronic and/or opto-electronic device according to claim 24, further comprising:
a first electrode in electrical connection with a first end of said transition-metal dichalcogenide crystal; and
a second electrode in electrical connection with a second end of said transition-metal dichalcogenide crystal spaced apart from said first end.

26. The electronic and/or opto-electronic device according to claim 25, further comprising a third electrode disposed proximate said transition-metal dichalcogenide crystal such that said third electrode is a gate electrode and said electronic and/or opto-electronic device is a field effect transistor.

27. The electronic and/or opto-electronic device according to claim 24, wherein said transition-metal dichalcogenide crystal is a nano-ribbon of one of MoS₂, MoSe₂, WS₂, or WSe₂.

28. A method of treating a silicon substrate for use in producing transition-metal dichalcogenide crystals, comprising:
providing a silicon substrate having a Si(001) crystal surface; and
exposing said Si(001) crystal surface of said silicon substrate to a dose of phosphine to provide a phosphine treated surface thereof.

29. The method of claim 28, wherein said dose of phosphine is at least 5 cm³ and less than 200 cm³.

30. The method of claim 28, wherein said dose of phosphine is at least 26 cm³ and less than 120 cm³.

31. The method of claim 28, wherein said Si(001) crystal surface of said silicon substrate is at least 5 cm² and less than 100 cm².

32. The method of claim 28, wherein said exposing said Si(001) crystal surface of said silicon substrate to said dose of phosphine uses a gas mixture comprising phosphine and a noble gas.

33. The method of claim 32, wherein said noble gas is helium.

34. The method of claim 32, wherein said gas mixture consists essentially of at least 10% phosphine with the remainder being at least one noble gas.

35. The method of claim 28, wherein said dose of phosphine is selected for producing a transition-metal dichalcogenide nanocrystal that is a nano-ribbon structure having a selected width.

36. The method of claim 28, wherein said treating said silicon substrate is performed at a temperature of at least 100° C. and less than 200° C.

37. The method of claim 28, wherein said treating said silicon substrate is performed at a temperature of at least 130° C. and less than 170° C.

38. The method of claim 28, wherein said treating said silicon substrate is performed at a temperature of about 150° C.

39. The method of claim 28, wherein said treating said silicon substrate is performed at a pressure of at least 5 Torr and less than 100 Torr.

40. The method of claim 28, wherein said treating said silicon substrate is performed at a pressure of about 80 Ton.

41. The method of claim 28, wherein said phosphine treated surface is a modified surface of a Si(001) crystal surface of a silicon substrate so as to have a surface composition containing Si and P in a stoichiometric proportion represent by SiₓP_{y} wherein x and y are each greater than 0 and less than 2 and subject to the constraint x+y=2.

42. The method according to claim 41, wherein x is at least 0.5 and less than 1 and y is at least 1 and less than about 1.5.

43. The method according to claim 41, wherein said phosphine treated surface of said silicon substrate comprises Si—P dimers.

44. A phosphine-treated silicon substrate for use in producing transition-metal dichalcogenide crystals on a phosphine treated surface thereof, wherein said phosphine treated surface is a modified surface of a Si(001) crystal surface of a silicon substrate so as to have a surface composition containing Si and P in a stoichiometric proportion represent by SiₓP_{y} wherein x and y are each greater than 0 and less than 2 and subject to the constraint x+y=2.

45. The phosphine-treated silicon substrate according to claim 44, wherein x is at least 0.5 and less than 1 and y is at least 1 and less than about 1.5.

46. The phosphine-treated silicon substrate according to claim 44, wherein said phosphine treated surface of said silicon substrate comprises Si—P dimers.

47. The method of claim 4, wherein said dose of phosphine is introduced at a flow rate of between no less than 1 sccm and no greater than 1000 sccm.

48. The method of claim 28, wherein said dose of phosphine is introduced at a flow rate of between no less than 1 sccm and no greater than 1000 sccm.
